(19) United States
(12) Patent Application Publication
(10) Pub. No.: US 2025/0006593 A1
(43) Pub. Date: Jan. 2, 2025

(54) SUBSTRATE CONTACT INTEGRATION IN GALLIUM NITRIDE DEVICES

(71) Applicant: Texas Instruments Incorporated, Dallas, TX (US)

(72) Inventors: Dong Seup Lee, McKinney, TX (US); Jungwoo Joh, Allen, TX (US); Hiroshi Yamasaki, Aizuwakamatsu-shi (JP); Hisayuki Shimada, Aizuwakamatsu-shi (JP); Kenichi Yoshikawa, Aizuwakamatsu-shi (JP)

(21) Appl. No.: 18/345,939

(22) Filed: Jun. 30, 2023

(51) Int. Cl. H01L 23/48; H01L 21/311; H01L 21/768; H01L 23/00; H01L 25/065; H01L 29/20

(52) U.S. Cl. CPC H01L 23/481; H01L 21/31144; H01L 21/7684; H01L 21/76877; H01L 21/76898; H01L 24/05; H01L 25/0657; H01L 29/2003; H01L 2224/05647; H01L 2225/06541; H01L 2924/1306

(57) ABSTRACT

A microelectronic device includes a semiconductor substrate with a III-N semiconductor layer over the semiconductor substrate. A substrate via opening extending through the III-N semiconductor layer and a substrate contact pad in the substrate via opening, contacting the semiconductor substrate provide a substrate contact. The microelectronic device also includes an inter-level dielectric layer with a planar surface over the substrate contact. The microelectronic device further includes an interconnect metal level over the inter-level dielectric layer. The substrate via opening is formed through the III-N semiconductor layer to expose the semiconductor substrate. The substrate contact pad is formed over the III-N semiconductor layer, extending into the substrate via opening and making contact with the semiconductor substrate, to form the substrate contact. The ILD layer is formed over the III-N semiconductor layer and the substrate contact pad, so that the ILD layer has a planar surface over the substrate via opening.

### TECHNICAL FIELD

This disclosure relates to the field of microelectronic devices. More particularly, but not exclusively, this disclosure relates to III-N semiconductor components in microelectronic devices.

### BACKGROUND

Gallium nitride (GaN) devices have gained considerable attention in recent years due to their exceptional electrical properties. These devices exhibit high breakdown voltage, high electron mobility, and excellent thermal conductivity, making them highly desirable for applications such as power switches. Some GaN devices are fabricated on silicon substrates. The use of silicon as a substrate offers several advantages, including its low cost, widespread availability, and compatibility with standard semiconductor processing techniques. Additionally, silicon has a well-established infrastructure for device fabrication and integration. In order to ensure efficient electrical functionality of GaN devices on silicon substrates, it is desired to establish suitable electrical substrate contacts between a reference node of the GaN component and the underlying silicon substrate. These contacts allow for maintaining constant bias in the silicon substrate and enable the GaN devices to handle higher currents. Integrating the substrate contacts to the silicon substrates while attaining desired circuit density has been challenging.

### SUMMARY

The present disclosure introduces a microelectronic device that includes a semiconductor substrate with a III-N semiconductor layer over the semiconductor substrate. The microelectronic device has a substrate via opening extending through the III-N semiconductor layer to the semiconductor substrate. The microelectronic device includes a substrate contact pad in the substrate via opening, contacting the semiconductor substrate, to provide a substrate contact. The microelectronic device also includes an inter-level dielectric (ILD) layer over the substrate contact pad in the substrate via opening. The ILD layer has a planar surface over the substrate via opening. The microelectronic device further includes an interconnect metal level over the ILD layer.

The microelectronic device is formed by forming the substrate via opening through the III-N semiconductor layer to expose the semiconductor substrate. The substrate contact pad is formed over the III-N semiconductor layer, extending into the substrate via opening and making contact with the semiconductor substrate, to form the substrate contact. The ILD layer is formed over the III-N semiconductor layer and the substrate contact pad, so that the ILD layer has a planar surface over the substrate via opening. The interconnect metal level is formed over the ILD layer.

### BRIEF DESCRIPTION OF THE FIGURES

FIG. 1A through FIG. 1AB are top views and cross sections of a microelectronic device having a substrate contact through a III-N semiconductor layer to a semiconductor substrate, depicted in successive stages of an example method of formation.

FIG. 2A through FIG. 2R are top views and cross sections of a microelectronic device having a substrate contact through a III-N semiconductor layer to a semiconductor substrate, depicted in successive stages of an example method of formation.

FIG. 3A through FIG. 3N are top views and cross sections of a microelectronic device having a substrate contact through a III-N semiconductor layer to a semiconductor substrate, depicted in successive stages of an example method of formation.

FIG. 4A through FIG. 4C are cross sections of a microelectronic device having a substrate contact through a III-N semiconductor layer to a semiconductor substrate, depicted in successive stages of example methods of formation.

FIG. 5A through FIG. 5D are cross sections of a microelectronic device having a substrate contact through a III-N semiconductor layer to a semiconductor substrate, depicted in successive stages of an example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

A microelectronic device includes a semiconductor substrate with a III-N semiconductor layer over the semiconductor substrate. The semiconductor substrate may include monocrystalline silicon, silicon carbide, or other semiconductor material. The microelectronic device has a substrate contact in a substrate via opening extending through the III-N semiconductor layer to the semiconductor substrate. The substrate contact includes a substrate contact pad in the substrate via opening. The substrate contact pad contacts the semiconductor substrate and makes an electrical connection to the semiconductor substrate. The microelectronic device includes an inter-level dielectric (ILD) layer over the substrate contact pad, extending across the substrate via opening. The ILD layer has a planar surface over the substrate via opening. The microelectronic device further includes an interconnect metal level, separate from the substrate contact pad, over the ILD layer. The microelectronic device includes an electrical connection to a top of the substrate contact pad.

The microelectronic device is formed by forming the substrate via opening through the III-N semiconductor layer to expose the semiconductor substrate. The substrate contact pad is formed over the III-N semiconductor layer, extending into the substrate via opening and making contact with the semiconductor substrate. The ILD layer is formed over the III-N semiconductor layer and the substrate contact pad. The ILD layer is formed so that the ILD layer has a planar surface over the substrate via opening. An interconnect metal level is formed over the ILD layer.

The substrate via opening may have a width at the semiconductor substrate that is less than two times a thickness of the III-N semiconductor layer, which may advantageously reduce an area of the microelectronic device compared to a similar microelectronic device having a wider substrate via opening. Having the planar surface of the ILD layer over the substrate via opening advantageously facilitates photolithography processes used to form the interconnect metal level proximate to the substrate via opening. This may enable linewidths of interconnect lines of the interconnect metal level and spaces between the interconnect lines, proximate to the substrate via opening, being less than a thickness of the III-N semiconductor layer, which may advantageously enable a reduced area for the microelectronic device.

It is noted that terms such as top, bottom, over, above, under, and below may be used in this disclosure. These terms should not be construed as limiting the position or orientation of a structure or element, but should be used to provide spatial relationship between structures or elements. For the purposes of this disclosure, the term “lateral” refers to a direction parallel to a plane of the top surface of the semiconductor substrate, and the term “vertical” is understood to refer to a direction perpendicular to the plane of the top surface of the semiconductor substrate. For the purposes of this disclosure, a structure or member that is disclosed as including “primarily” a substance has more than 50 percent, by weight, of that substance. For example, a dielectric layer that is disclosed to include primarily silicon nitride has more than 50 percent, by weight, of silicon nitride.

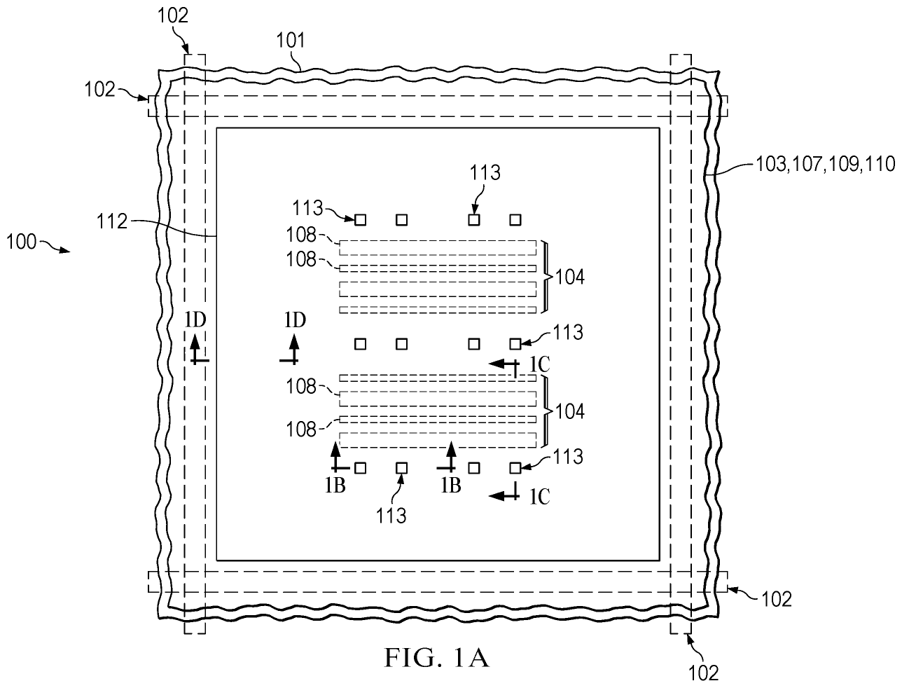

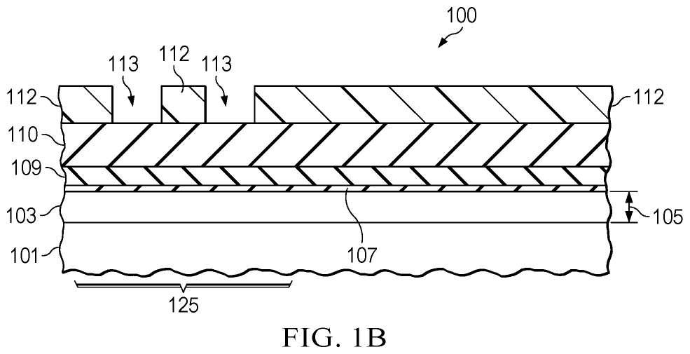

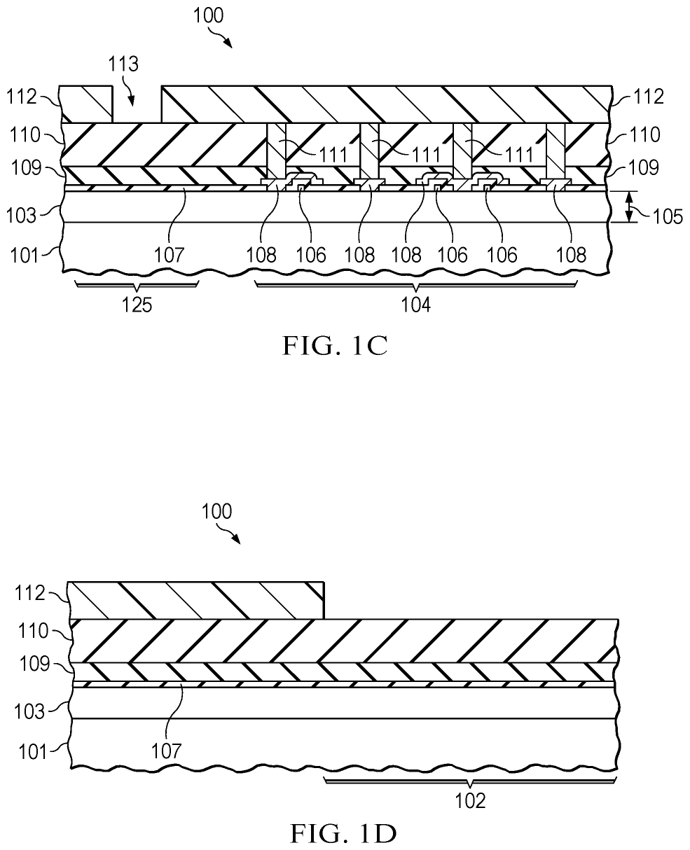

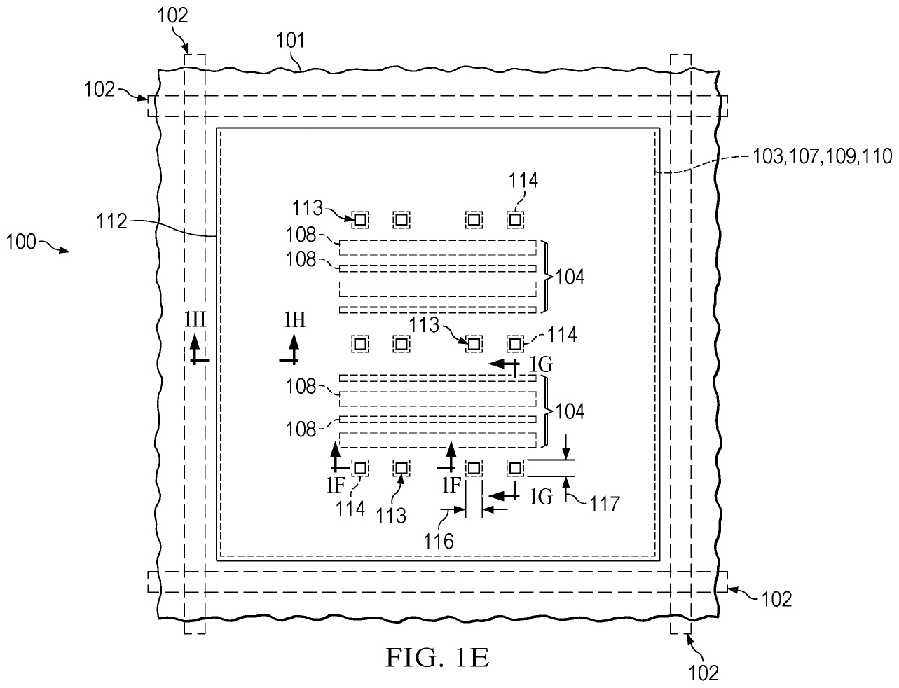

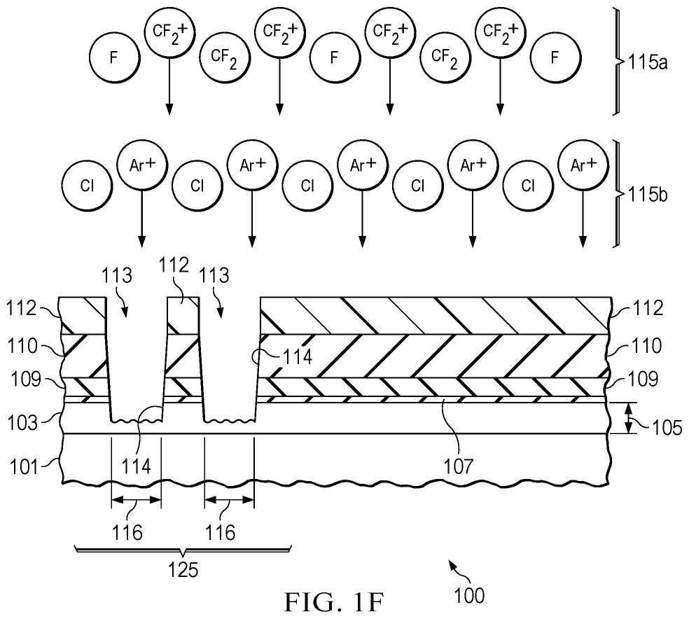

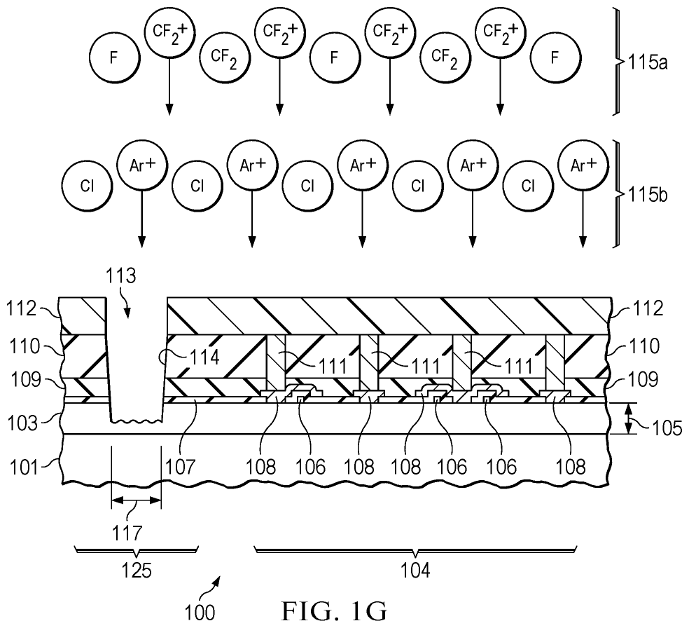

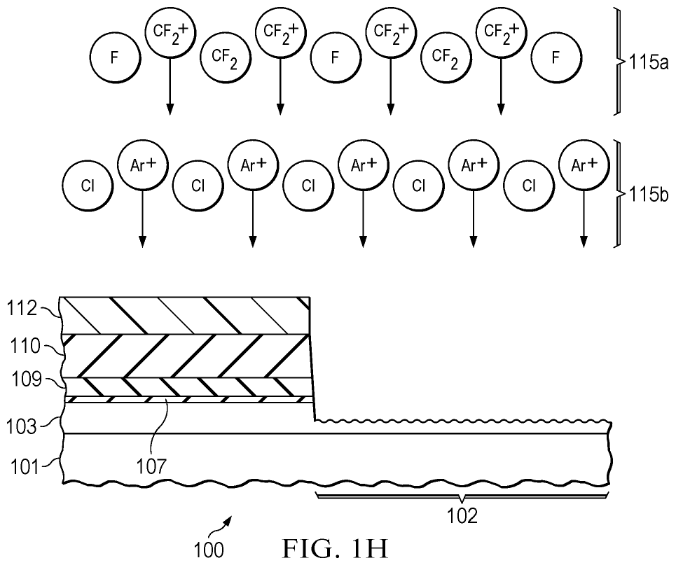

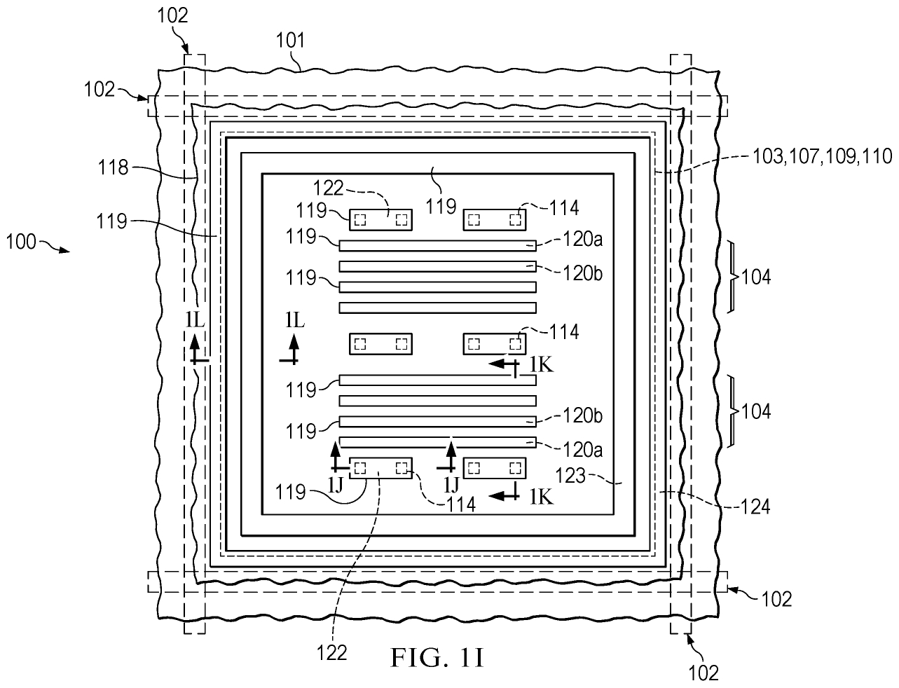

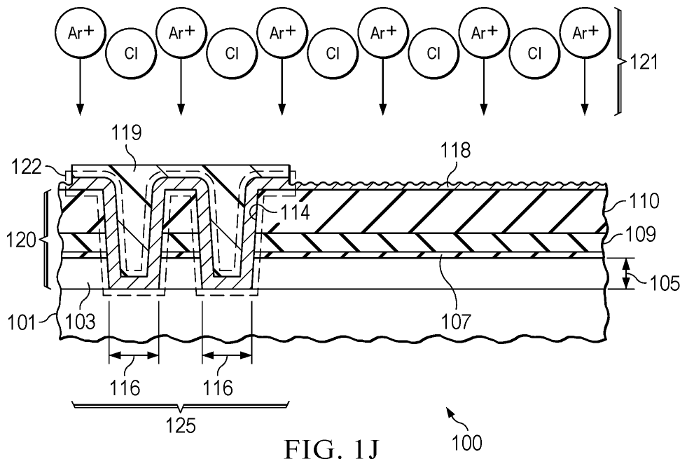

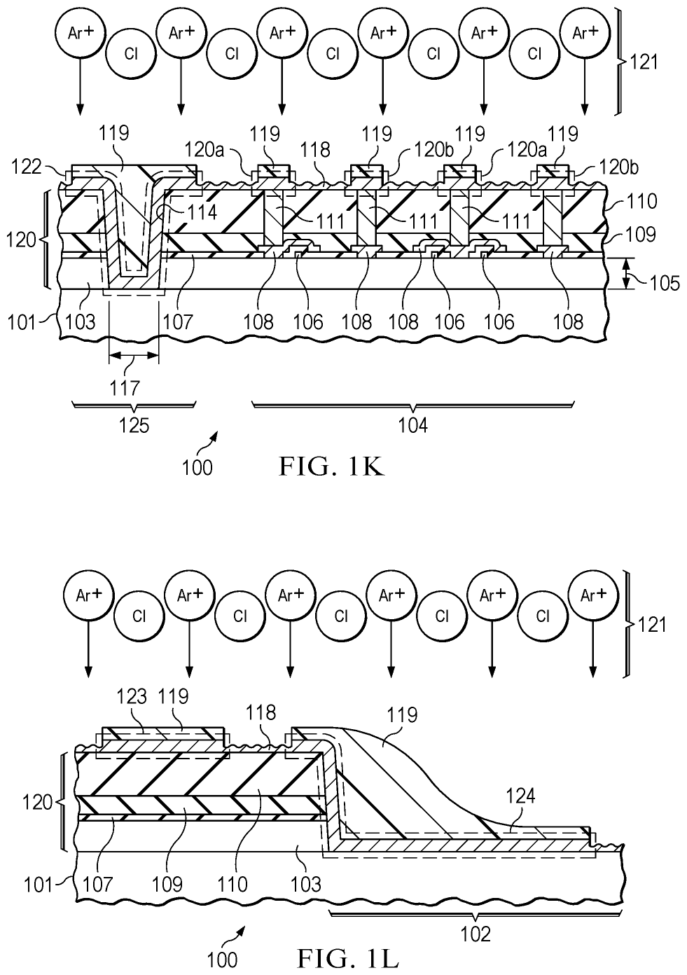

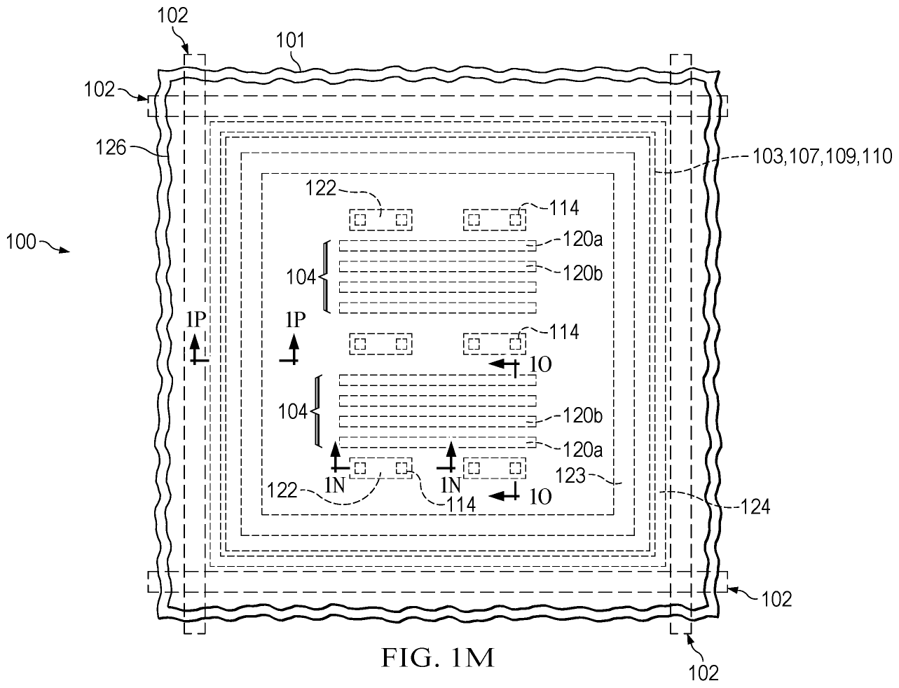

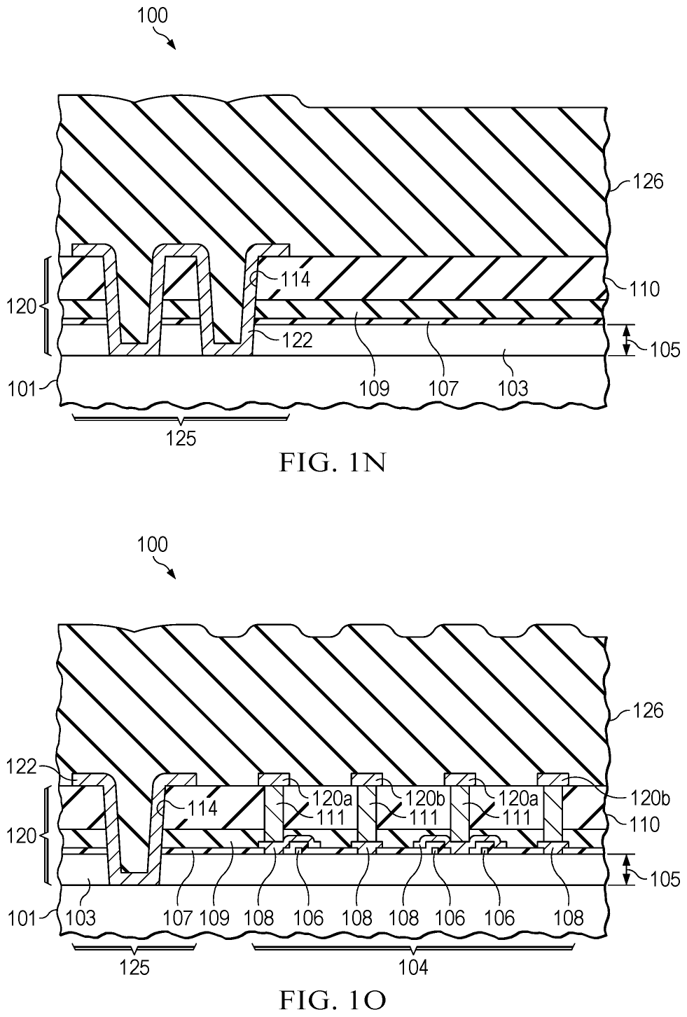

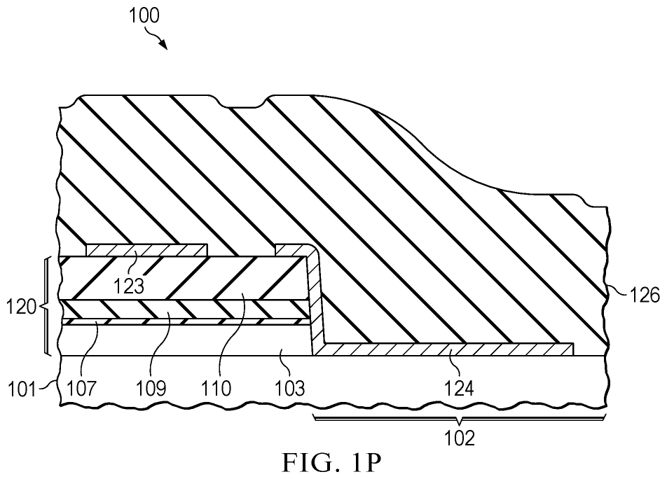

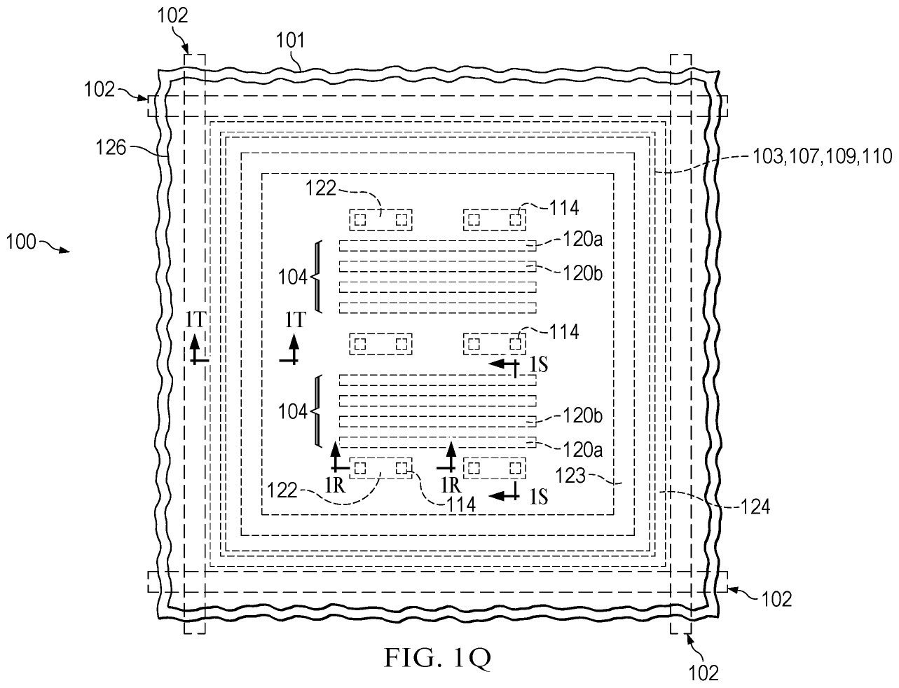

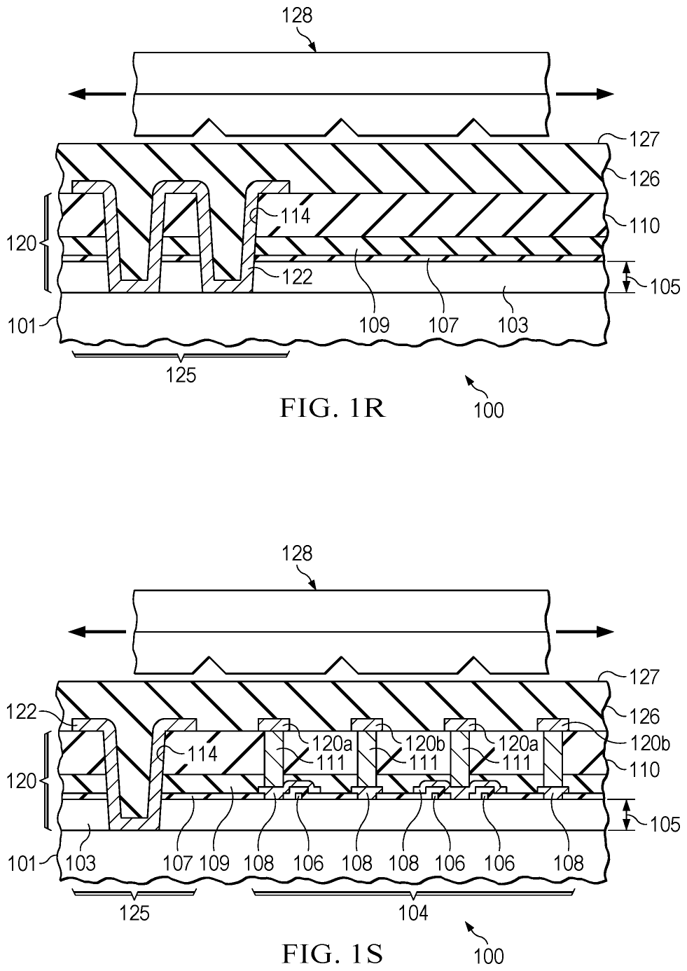

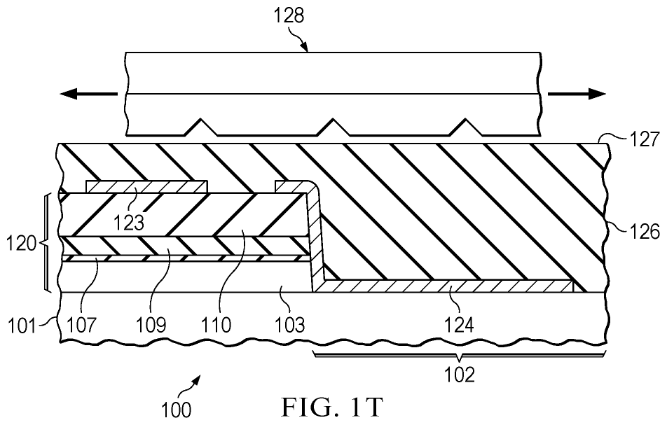

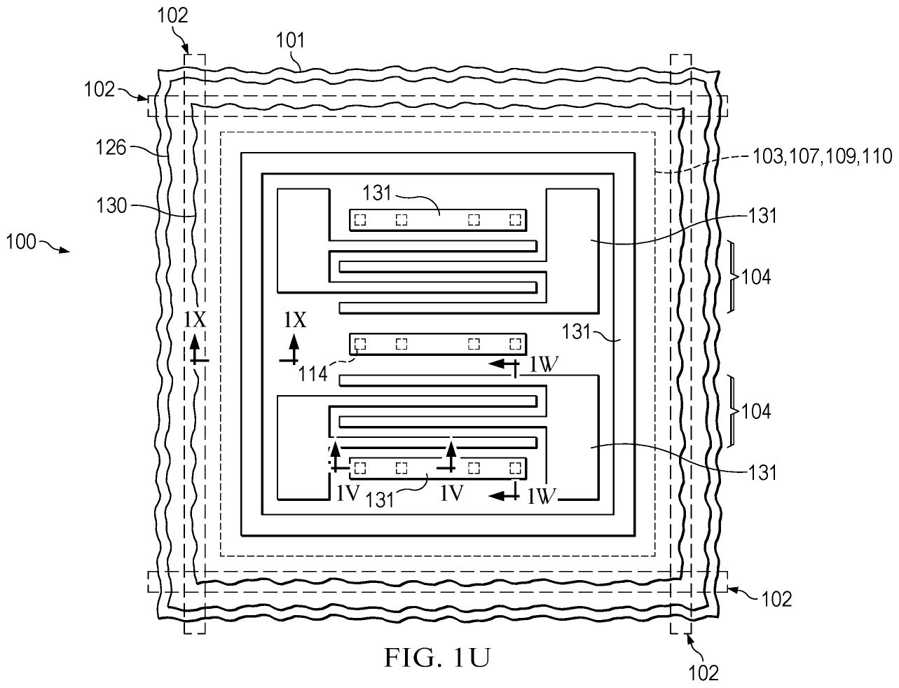

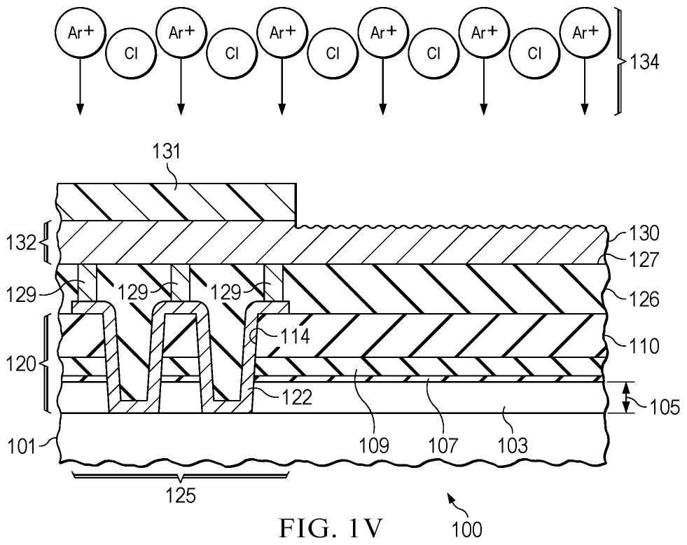

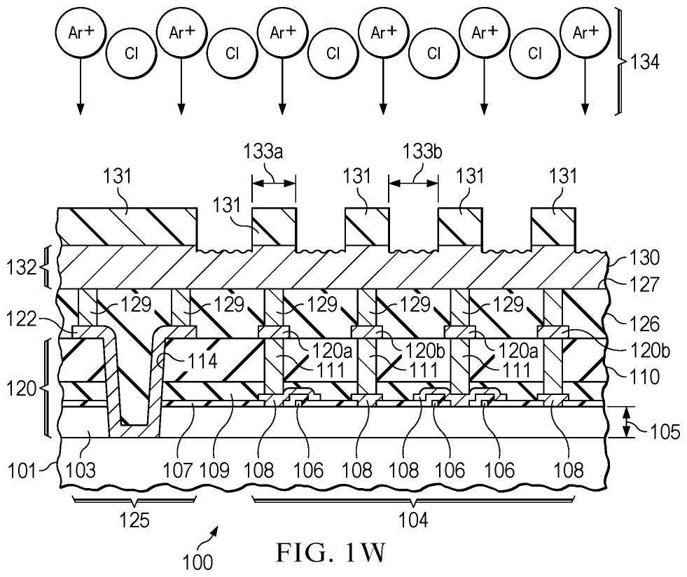

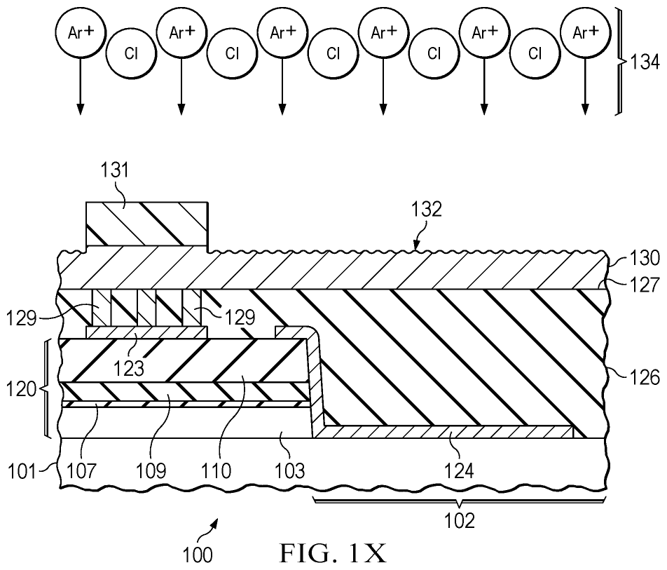

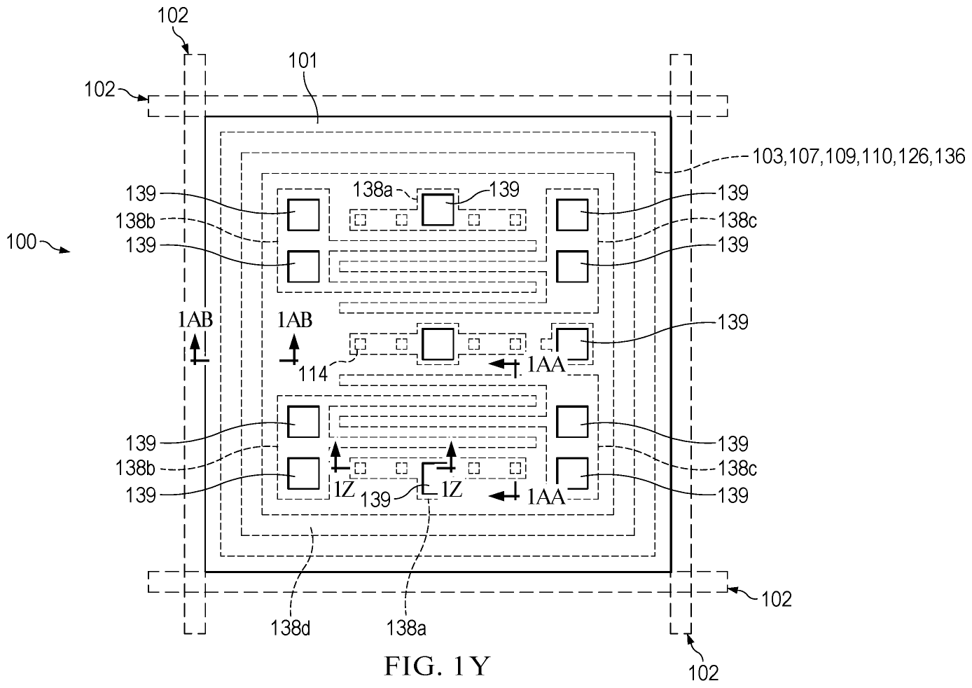

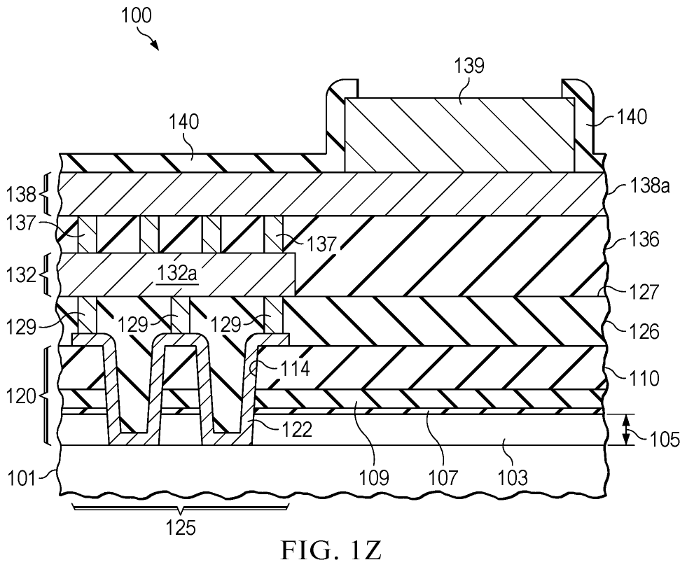

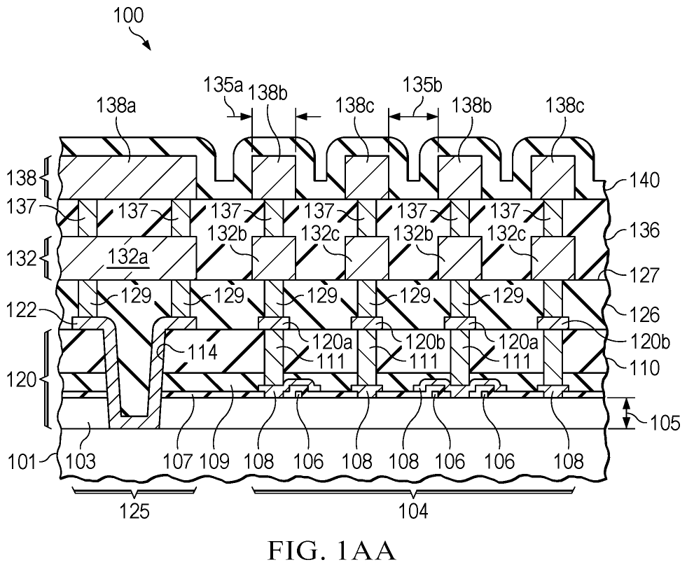

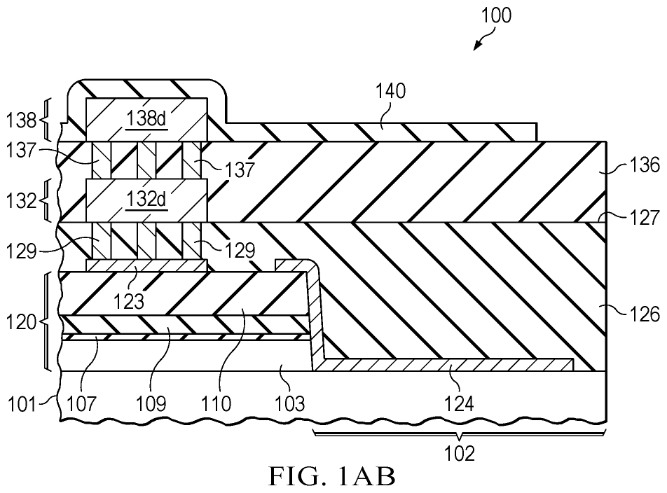

FIG. 1A through FIG. 1AB are top views and cross sections of a microelectronic device having a substrate contact through a III-N semiconductor layer to a semiconductor substrate, depicted in successive stages of an example method of formation. FIG. 1A is a top view of the microelectronic device 100 at a first stage of formation, and FIG. 1B, FIG. 1C, and FIG. 1D are cross sections of the microelectronic device 100 of FIG. 1A. Referring to FIG. 1A through FIG. 1D, the microelectronic device 100 is formed on the semiconductor substrate 101. The semiconductor substrate 101 may be, for example, part of a bulk semiconductor wafer, part of a silicon-on-insulator (SOI) wafer, part of a MEMS substrate, or other workpiece suitable for forming the microelectronic device 100. The semiconductor substrate 101 may include additional microelectronic devices, not specifically shown. The microelectronic device 100 has not been singulated at this stage of formation, that is, the semiconductor substrate 101 extends past a perimeter of the microelectronic device 100 into singulation lanes 102 around the microelectronic device 100. The semiconductor substrate 101 will be singulated through the singulation lanes 102 to remove any excess material from the semiconductor substrate 101 and separate the microelectronic device 100 from the additional microelectronic devices, if any.

The microelectronic device 100 includes a III-N semiconductor layer 103 over the semiconductor substrate 101, extending across the microelectronic device 100 and across the singulation lanes 102. The III-N semiconductor layer 103 may include a nucleation layer, not specifically shown, of aluminum nitride on the semiconductor substrate 101. The III-N semiconductor layer 103 may include a graded region, not specifically shown, above the nucleation layer, in which a concentration of aluminum decreases, and a concentration of gallium increases, with vertical distance from the semiconductor substrate 101. The III-N semiconductor layer 103 may include a low defect region, not specifically shown, sometimes referred to as an unintentionally doped (UID) region, above the graded region, having essentially gallium nitride, optionally with some unintentional dopants. The III-N semiconductor layer 103 may include a channel sublayer, not specifically shown, above the low defect region, having essentially gallium nitride, to support a two-dimensional electronic gas (2DEG) during operation of the microelectronic device 100. The III-N semiconductor layer 103 may include a barrier layer, not specifically shown, of aluminum nitride or aluminum gallium nitride, over the channel sublayer.

The III-N semiconductor layer 103 may be formed by a sequence of vapor phase epitaxial processes. The vapor phase epitaxial processes may use a nitrogen-containing gas reagent such as ammonia, an aluminum-containing gas reagent such as trimethyl aluminum, and a gallium-containing gas reagent such as trimethyl gallium. In some versions of this example, the III-N semiconductor layer 103 may be formed on the semiconductor substrate 101 prior to acquisition of the semiconductor substrate 101 with the III-N semiconductor layer 103 by a facility performing the remaining operations disclosed for forming the microelectronic device 100.

In this example, the microelectronic device 100 includes an active component 104, depicted as a gallium nitride field effect transistor 104 formed in and on the III-N semiconductor layer 103. The gallium nitride field effect transistor 104 will be referred to as the GaN FET 104 herein. Other active components, such as a gallium nitride Schottky diode, are within the scope of this example.

A thickness 105 of the III-N semiconductor layer 103 depends on a maximum operating potential of the active component 104. By way of example, for a maximum operating potential of 100 volts, the thickness 105 may be 1.2 microns to 1.8 microns. For a maximum operating potential of 200 volts, the thickness 105 may be 2.5 microns to 3.5 microns. Other ranges for the thickness 105 are within the scope of this example.

A gate structure 106 of the GaN FET 104, shown in FIG. 1C, is formed over the III-N semiconductor layer 103. The gate structure 106 may include, by way of example, a doped gallium nitride work function segment over the III-N semiconductor layer 103 and a metal bus segment on the doped gallium nitride work function segment. The doped gallium nitride work function segment and the metal bus segment may be patterned separately or concurrently. Other compositions and layer configurations for the gate structure 106 are within the scope of this example.

A first pre-metal dielectric (PMD) layer 107 is formed over the III-N semiconductor layer 103 and over the gate structure 106. The first PMD layer 107 may include primarily silicon nitride. The first PMD layer 107 may be formed by a low pressure chemical vapor deposition (LPCVD) process to attain a hydrogen content less than 10 atomic percent.

Source/drain pads 108 are formed through the first PMD layer 107 to make electrical connections to source and drain regions of the GaN FET 104. The source/drain pads 108 may include a lower adhesion sublayer of titanium on the first PMD layer 107 to advantageously provide adhesion to the silicon nitride in the first PMD layer 107 and to provide a lower barrier layer to reduce aluminum grain deformation. The source/drain pads 108 may include a main sublayer of primarily aluminum on the lower adhesion sublayer. The main sublayer may be 100 nanometers to 500 nanometers thick, by way of example, to provide a low resistance connection to the source and drain regions of the GaN FET 104. The source/drain pads 108 may include an upper barrier sublayer of titanium nitride on the main sublayer, to reduce aluminum hillock formation. The source/drain pads 108 may include an upper adhesion sublayer of titanium to provide adhesion to silicon nitride in a second PMD layer 109 on the source/drain pads 108. The first PMD layer 107 may be etched using a first etch mask, not specifically shown, to expose the III-N semiconductor layer 103 in the source and drain regions, followed by formation of a source/drain metal layer stack, not specifically shown, on the first PMD layer 107, extending to the source and drain regions. The sublayers of the source/drain metal layer stack may be formed by a sequence of sputter and reactive sputter processes. The source/drain metal layer stack is subsequently etched using a second etch mask, not specifically shown, to form the source/drain pads 108.

The second PMD layer 109 is formed over the first PMD layer 107 and the source/drain pads 108. The second PMD layer 109 may include primarily silicon nitride, and may be thicker than the source/drain pads 108. The second PMD layer 109 may be formed by a plasma enhanced chemical vapor deposition (PECVD) process to maintain the temperature of the microelectronic device 100 below a temperature that would degrade the main sublayer of the source/drain pads 108, for example, below 300° C. The second PMD layer 109 may optionally be planarized.

A third PMD layer 110 is formed over the second PMD layer 109. The third PMD layer 110 may include primarily silicon dioxide. The third PMD layer 110 may be formed by a PECVD process or a high density plasma (HDP) process to maintain the temperature of the microelectronic device 100 below the temperature that would degrade the main sublayer of the source/drain pads 108. The third PMD layer 110 may be sufficiently thick to provide dielectric isolation between source and drain potentials, and to reduce capacitive coupling, during operation of the microelectronic device 100. By way of example, the third PMD layer 110 may be 1 micron to 5 microns thick.

Contacts 111 are formed through the third PMD layer 110 and the second PMD layer 109 to make electrical connections to the source/drain pads 108. The contacts 111 may be formed by etching contact holes through the third PMD layer 110 and the second PMD layer 109 to expose portions of the source/drain pads 108. The contacts 111 may include an adhesion liner of titanium, formed by a sputter process over the third PMD layer 110, extending into the contact holes and on the exposed portions of the source/drain pads 108. The contacts 111 may include a barrier liner of titanium nitride on the adhesion liner, extending into the contact holes, to protect the third PMD layer 110 from chemical degradation during subsequent reduction of tungsten hexafluoride. The barrier liner may be formed by a reactive sputter process or an atomic layer deposition (ALD) process. The contacts 111 may include a fill plug of tungsten on the barrier liner, formed by a metal organic chemical vapor deposition (MOCVD) process including reduction of tungsten hexafluoride. The tungsten, barrier liner and adhesion liner on a top surface of the third PMD layer 110 are removed, leaving the tungsten, barrier liner and adhesion liner in the contact holes to provide the contacts 111. The tungsten, barrier liner and adhesion liner may be removed from the top surface of the third PMD layer 110 by a chemical mechanical polish (CMP) process, an etchback process, or a combination of both.

A substrate via etch mask 112 is formed over the third PMD layer 110 and the contacts 111, exposing the third PMD layer 110 in substrate via areas 113 for substrate via openings 114, shown in FIG. 1E through FIG. 1H. Referring back to FIG. 1A through FIG. 1D, the substrate via etch mask 112 may expose the third PMD layer 110 in the singulation lanes 102, as shown in FIG. 1D. The substrate via etch mask 112 may include photoresist, formed by a photolithographic process. The substrate via etch mask 112 may include anti-reflection material, such as an organic bottom anti-reflection coating (BARC) under the photoresist.

FIG. 1E is a top view of the microelectronic device 100 at a subsequent stage of formation, and FIG. 1F, FIG. 1G, and FIG. 1H are cross sections of the microelectronic device 100 of FIG. 1D. Referring to FIG. 1E through FIG. 1H, the third PMD layer 110, the second PMD layer 109, and the first PMD layer 107 are removed where exposed by the substrate via etch mask 112 to expose the III-N semiconductor layer 103 and form upper portions of substrate via openings 114, by a first reactive ion etch (RIE) process 115a. The first RIE process 115a uses one or more halogen etchant species, such as carbon tetrafluoride (CF₄) or ethane tetrafluoride (C₂F₆). Radio frequency (RF) power, is applied to the halogen etchant species to generate electrons, ions, such as CF₂⁺, and radicals, that is, neutral species having an unpaired electrons, such as atomic fluorine (F) and CF₂, as depicted schematically in FIG. 1F, FIG. 1G and FIG. 1H. Other species of ions and radicals in the first RIE process 115a are within the scope of this example. During the first RIE process 115a, the microelectronic device 100 is biased at a negative potential with respect to the plasma, attracting positive ions which impact the third PMD layer 110, the second PMD layer 109, and the first PMD layer 107 with sufficient kinetic energy to disrupt covalent bonds, while the radicals diffuse to the surface and react with the silicon to form volatile silicon products such as SiF₄, which are evacuated. The first RIE process 115a may change halogen etchant species when transitioning between etching silicon dioxide and etching silicon nitride. The first RIE process 115a may be endpointed, or may be a timed etch. In this example, the third PMD layer 110, the second PMD layer 109, and the first PMD layer 107 are removed from the singulation lanes 102 by the first RIE process 115a concurrently with the substrate via openings 114.

The III-N semiconductor layer 103 is removed where exposed by the etched first PMD layer 107 to form lower portions of the substrate via openings 114 that expose the semiconductor substrate 101, by a second RIE process 115b. The second RIE process 115b may be performed in an inductively coupled plasma (ICP) etcher, which generates a plasma containing chemically reactive neutral species, ions, and electrons. The second RIE process 115b uses a chemical etchant species, such as chlorine gas (Cl₂), silicon tetrachloride (SiCl₄), boron trichloride (BCl₃), or boron tribromide (BBr₃), and a physical etchant species, such as argon (Ar), helium, (He), oxygen (O₂), or silicon tetrafluoride (SiF₄). The ICP etcher has a first power supply for forming a plasma using the chemical etchant species and the physical etchant species to generate electrons, ions, such as Ar⁺ depicted schematically in FIG. 1E and FIG. 1F, He⁺, O⁺, or F⁺, and radicals, such as atomic chlorine (Cl), depicted schematically in FIG. 1E and FIG. 1F, or atomic bromine (Br). The ICP etcher has a second power supply to independently control a potential difference between the plasma and the microelectronic device 100. During the second RIE process 115b, the ions impact the III-N semiconductor layer 103, imparting sufficient energy to facilitate separation of the nitrogen atoms from the gallium atoms and the aluminum atoms. The radicals bind to the gallium atoms and the aluminum atoms to form volatile products that are removed. The first power supply may be operated at a power of 250 watts to 500 watts, for a 125 millimeter wafer, by way of example. The second power supply may be adjusted to operate at 20 watts to 100 watts, to provide an impact energy of the physical etchant species sufficient to facilitate separation of the gallium atoms and nitrogen atoms. FIG. 1F, FIG. 1G, and FIG. 1H depict the second RIE process 115b partway to completion. In this example, the III-N semiconductor layer 103 is removed from the singulation lanes 102, to facilitate subsequent singulation of the microelectronic device 100, by the second RIE process 115b concurrently with the substrate via openings 114, advantageously reducing process complexity and cost compared to removing the III-N semiconductor layer 103 from the singulation lanes 102 in a separate process operation. After the second RIE process 115b is completed, the singulation lanes 102 are free of the III-N semiconductor layer 103.

After the second RIE process 115b is completed, the substrate via etch mask 112 is removed. The substrate via etch mask 112 may be removed by a plasma process using oxygen radicals and ions, such as an asher process, followed by a wet clean process using an aqueous mixture of hydrogen peroxide and ammonium hydroxide. Alternatively, the substrate via etch mask 112 may be removed by a wet strip process using n-methyl pyrrolidone (NMP) or an aqueous mixture of sulfuric acid and hydrogen peroxide, followed by an asher process, followed by a wet clean process.

In some versions of this example, the substrate via openings 114 may have a width 116 at the semiconductor substrate 101 that is less than two times the thickness 105 of the III-N semiconductor layer 103, which may advantageously reduce an area of the microelectronic device 100 compared to a similar microelectronic device having a wider substrate via opening. In some versions, the substrate via openings 114 may have a length 117, perpendicular to the width 116, at the semiconductor substrate 101 that is less than two times the width 116, which may further advantageously reduce the area of the microelectronic device 100. In other versions, the width 116 of the substrate via openings 114 may be greater than two times the thickness 105 of the III-N semiconductor layer 103. In other versions, the length 117 of the substrate via openings 114 may be greater than two times the width 116.

FIG. 1I is a top view of the microelectronic device 100 at a subsequent stage of formation, and FIG. 1J, FIG. 1K, and FIG. 1L are cross sections of the microelectronic device 100 of FIG. 1I. Referring to FIG. 1I through FIG. 1L, a contact metal layer stack 118 is formed over the third PMD layer 110, making electrical connections to the contacts 111, and extending into the substrate via openings 114, making electrical connections to the semiconductor substrate 101. The contact metal layer stack 118 also extends into the singulation lanes 102.

The contact metal layer stack 118 may include a lower adhesion sublayer of titanium on the third PMD layer 110 to advantageously provide adhesion to the silicon dioxide in the third PMD layer 110. The contact metal layer stack 118 may include a lower barrier sublayer of titanium nitride on the lower adhesion sublayer to reduce aluminum grain deformation and provide an anti-reflection sublayer to facilitate subsequent photolithographic processing. The contact metal layer stack 118 may include a main sublayer of primarily aluminum on the lower barrier sublayer. The main sublayer may be 500 nanometers to 1 micron thick, by way of example, to provide low resistance connections to the contacts 111 and to the semiconductor substrate 101. The contact metal layer stack 118 may include an upper electromigration sublayer of titanium on the main sublayer, to reduce aluminum grain deformation. The contact metal layer stack 118 may include an upper barrier sublayer of titanium nitride on the upper electromigration sublayer to reduce aluminum hillock formation.

A contact metal etch mask 119 is formed over the contact metal layer stack 118, covering areas for members of a pad interconnect layer 120, including substrate contact pads 122, source pads 120a, drain pads 120b, a lower scribe seal pad 123, and a singulation lane seal 124. The singulation lane seal 124 extends over an edge of the III-N semiconductor layer 103 and onto the semiconductor substrate 101 in the singulation lanes 102. The lower scribe seal pad 123 extends around the GaN FET 104 and is proximate to the singulation lane seal 124. The contact metal etch mask 119 may include photoresist, patterned by a photolithographic process, and may include anti-reflection material such as a BARC. The contact metal etch mask 119 may fill the substrate via openings 114, advantageously enabling patterning smaller linewidths and spaces, as a result of the substrate via openings 114 having have widths 116 at the semiconductor substrate 101 that are less than two times the thickness 105 of the III-N semiconductor layer 103, compared to a similar microelectronic device with wider substrate via openings. The contact metal etch mask 119 may expose the contact metal layer stack 118 in a central portion of the singulation lanes 102, enabling the contact metal layer stack 118 to be removed from the central portion of the singulation lanes 102, advantageously facilitating subsequent singulation of the microelectronic device 100. In some alternate versions of this example, the contact metal etch mask 119 may expose the contact metal layer stack 118 across the singulation lanes 102, so that the singulation lane seal 124, as depicted in FIG. 1L, is not formed. In other alternate versions, the contact metal layer stack 118 may be unpatterned across the singulation lanes 102, that is, the contact metal etch mask 119 may extend across the singulation lanes 102, so that the singulation lane seal 124 extends contiguously across the singulation lanes 102.

The contact metal layer stack 118 is patterned by removing the contact metal layer stack 118 where exposed by the contact metal etch mask 119, using a first aluminum RIE process 121. The first aluminum RIE process 121 may use a physical etchant species, such as argon ions, and a chemical etchant species, such as chlorine radicals, as shown schematically in FIG. 1J, FIG. 1K and FIG. 1L, to etch the main sublayer of the contact metal layer stack 118. Other chemistries to etch the main sublayer are within the scope of this example. The upper barrier sublayer, the upper electromigration sublayer, the lower barrier sublayer, and the lower adhesion sublayer may be removed by other RIE processes using fluorine radicals, by way of example. FIG. 1J, FIG. 1K and FIG. 1L depict removal of the contact metal layer stack 118 partway to completion. After the contact metal layer stack 118 is patterned by removing the contact metal layer stack 118 where exposed by the contact metal etch mask 119, the remaining contact metal layer stack 118 under the contact metal etch mask 119 provides the members of the pad interconnect layer 120, including the substrate contact pads 122, the source pads 120a, the drain pads 120b, the lower scribe seal pad 123, and the singulation lane seal 124. A combination of the substrate via openings 114 and the substrate contact pads 122 extending into the substrate via openings 114 and making electrical connections to the semiconductor substrate 101 provides substrate vias 125 of the microelectronic device 100. In this example, the substrate contact pads 122 extend above the III-N semiconductor layer 103 adjacent to the substrate via openings 114. In the version of this example in which the contact metal etch mask 119 exposes the contact metal layer stack 118 across the singulation lanes 102, the first aluminum RIE process 121 removes the contact metal layer stack 118 from the exposed semiconductor substrate 101 in the singulation lanes 102 and from the third PMD layer 110 adjacent to the singulation lanes 102. Depending on a slope angle of an edge of the III-N semiconductor layer 103 at the singulation lanes 102, the first aluminum RIE process 121 may remove the contact metal layer stack 118 from the edge of the III-N semiconductor layer 103, or may leave a portion of the contact metal layer stack 118 on the edge of the III-N semiconductor layer 103.

After the contact metal layer stack 118 is patterned, the contact metal etch mask 119 is removed. The contact metal etch mask 119 may be removed using an asher process, by way of example.

FIG. 1M is a top view of the microelectronic device 100 at a subsequent stage of formation, and FIG. 1N, FIG. 1O, and FIG. 1P are cross sections of the microelectronic device 100 of FIG. 1M. Referring to FIG. 1M through FIG. 1P, a first ILD layer 126 is formed over the third PMD layer 110, the members of the pad interconnect layer 120, and extending into the singulation lanes 102. The first ILD layer 126 may include primarily silicon dioxide, and may be formed by a PECVD process or an HDP process to maintain the temperature of the microelectronic device 100 below the temperature that would degrade the main sublayer of the source/drain pads 108 and the members of the pad interconnect layer 120. The first ILD layer 126 may include a sublayer of silicon nitride to reduce moisture infiltration from the singulation lanes 102 into the silicon dioxide of the third PMD layer 110.

The first ILD layer 126 of this example has a non-planar top surface, due to the substrate via openings 114 and the singulation lanes 102. Patterning photoresist over the first ILD layer 126 proximate to the substrate via openings 114 would be difficult, due to thickness variations in the photoresist due to the non-planar top surface of the first ILD layer 126. The first ILD layer 126 may be sufficiently thick to provide dielectric isolation between source and drain potentials, and to reduce capacitive coupling, during operation of the microelectronic device 100. The first ILD layer 126 may completely fill the substrate via openings 114 and the singulation lanes 102, so that a top surface of the first ILD layer 126 is everywhere above the members of the pad interconnect layer 120 and the third PMD layer 110. By way of example, the first ILD layer 126 may be 2 microns to 5 microns thick.

FIG. 1Q is a top view of the microelectronic device 100 at a subsequent stage of formation, and FIG. 1R, FIG. 1S, and FIG. 1T are cross sections of the microelectronic device 100 of FIG. 1Q. Referring to FIG. 1Q through FIG. 1T, the first ILD layer 126 is planarized over the substrate via openings 114, to form a planar top surface 127 of the first ILD layer 126. The planarity of the planar top surface 127 may extend over the III-N semiconductor layer 103, as indicated in FIG. 1R, FIG. 1S, and FIG. 1T. The first ILD layer 126 may be planarized by an oxide CMP process, as indicated by the CMP pad 128. Other processes for planarizing the first ILD layer 126, such as an etchback process, are within the scope of this example.

FIG. 1U is a top view of the microelectronic device 100 at a subsequent stage of formation, and FIG. 1V, FIG. 1W, and FIG. 1X are cross sections of the microelectronic device 100 of FIG. 1U. Referring to FIG. 1U through FIG. 1X, first vias 129 are formed through the first ILD layer 126 to make electrical connections to the members of the pad interconnect layer 120. The first vias 129 may have a composition and a structure similar to the contacts 111, and may be formed by a similar process sequence. Other compositions and structures for the first vias 129, such as copper vias on a barrier liner, formed by a copper damascene process, are within the scope of this example.

A first interconnect metal layer stack 130 is formed over the first ILD layer 126, making electrical connections to the first vias 129. The first interconnect metal layer stack 130 may have a sublayer structure and composition similar to the contact metal layer stack 118 of FIG. 1I through FIG. 1L, including a lower adhesion sublayer on the first ILD layer 126, a lower barrier sublayer on the lower adhesion sublayer, a main sublayer of primarily aluminum on the lower barrier sublayer, an upper electromigration sublayer on the main sublayer, and an upper barrier sublayer on the upper electromigration sublayer. The main sublayer may be 3 microns to 5 micron thick, by way of example, to provide low resistance to lateral currents between the GaN FET 104 and input/output terminals of the microelectronic device 100.

A first interconnect etch mask 131 is formed over the first interconnect metal layer stack 130, covering areas for members of a first interconnect level 132. The first interconnect etch mask 131 may include photoresist, formed by a photolithographic process, and may include anti-reflection material, such as BARC. The first interconnect etch mask 131 may have linewidths 133a proximate to one or more of the substrate via openings 114 that are less than the thickness 105 of the III-N semiconductor layer 103, which may be enabled by the planarity of the planar top surface 127 of the first ILD layer 126. The first interconnect etch mask 131 may have spaces 133b proximate to one or more of the substrate via openings 114 that are less than the thickness 105 of the III-N semiconductor layer 103, which may also be enabled by the planarity of the planar top surface 127 of the first ILD layer 126. Having the linewidths 133a and the spaces 133b less than the thickness 105 of the III-N semiconductor layer 103 may advantageously enable a reduced area of the microelectronic device 100.

The first interconnect metal layer stack 130 is removed where exposed by the first interconnect etch mask 131, using a second aluminum RIE process 134, along with other RIE processes using fluorine radicals, to form the members of the first interconnect level 132. The second aluminum RIE process 134 may use the physical etchant species and the chemical etchant species disclosed in reference to the first aluminum RIE process 121 of FIG. 1J, FIG. 1K and FIG. 1L. FIG. 1V, FIG. 1W, and FIG. 1X depict the first aluminum RIE process 121 partway to completion.

After the first interconnect metal layer stack 130 is removed where exposed by the first interconnect etch mask 131, the first interconnect etch mask 131 is removed. The first interconnect etch mask 131 may be removed using a process similar to the process used to remove the contact metal etch mask 119 of FIG. 1J, FIG. 1K and FIG. 1L.

FIG. 1Y is a top view of the microelectronic device 100 at a subsequent stage of formation, and FIG. 1Z, FIG. 1AA, and FIG. 1AB are cross sections of the microelectronic device 100 of FIG. 1Y. Referring to FIG. 1Y through FIG. 1AB, members of the first interconnect level 132 include first substrate interconnects 132a, first source interconnects 132b, first drain interconnects 132c, and a first scribe seal interconnect 132d.

The first interconnect level 132 is thicker than the substrate contact pads 122. The first interconnect level 132 may have linewidths 135a proximate to one or more of the substrate via openings 114 that are less than the thickness 105 of the III-N semiconductor layer 103, resulting from the planarity of the planar top surface 127 of the first ILD layer 126, by way of the first interconnect etch mask 131 of FIG. 1V, FIG. 1W, and FIG. 1X. The first interconnect level 132 may have spaces 135b proximate to one or more of the substrate via openings 114 that are less than the thickness 105 of the III-N semiconductor layer 103, also resulting from the planarity of the planar top surface 127 of the first ILD layer 126, by way of the first interconnect etch mask 131. Having the linewidths 135a and the spaces 135b less than the thickness 105 of the III-N semiconductor layer 103 may advantageously enable a reduced area of the microelectronic device 100.

A second ILD layer 136 may be formed over the first ILD layer 126 and the first interconnect level 132. The second ILD layer 136 may include primarily silicon dioxide, and may be formed by a PECVD process. The second ILD layer 136 may be 1 micron to 5 microns thick, by way of example. The second ILD layer 136 may be planarized to facilitate subsequent photolithography processes.

Second vias 137 may be formed through the second ILD layer 136 to make electrical connections to the members of the first interconnect level 132. The second vias 137 may have a composition and a structure similar to the first vias 129, and may be formed by a similar process sequence. Other compositions and structures for the second vias 137 are within the scope of this example.

A second interconnect level 138 may be formed on the second ILD layer 136, making electrical connections to the second vias 137. The second interconnect level 138 may have a layer structure and composition similar to the first interconnect level 132, and may be formed by a similar process sequence. The second interconnect level 138 may include a main sublayer 3 microns to 5 micron thick, by way of example, to provide low resistance to lateral currents between the GaN FET 104 and input/output terminals of the microelectronic device 100. Members of the second interconnect level 138 include second substrate interconnects 138a, second source interconnects 138b, second drain interconnects 138c, and a second scribe seal interconnect 138d. The second interconnect level 138 may have linewidths and spaces proximate to one or more of the substrate via openings 114 that are less than the thickness 105 of the III-N semiconductor layer 103, similar to the first interconnect level 132, resulting from the planarity of the planar top surface 127 of the first ILD layer 126, accruing the advantage of enabling a reduced area of the microelectronic device 100.

Input/output terminals 139 are formed, making electrical connections to the second interconnect level 138. The input/output terminals 139 may be manifested as wire bond pads, as depicted in FIG. 1Y and FIG. 1Z, bump bond pads, copper pillars, or other terminal configuration. A protective overcoat (PO) layer 140 may be formed over the second ILD layer 136 and the second interconnect level 138, with openings over the input/output terminals 139. The PO layer 140 may include polyimide, silicon dioxide, silicon nitride, silicon oxynitride, or any combination thereof. The PO layer 140 is not shown in FIG. 1Y, for clarity, but is shown in FIG. 1Z through FIG. 1AB.

The microelectronic device 100 is subsequently singulated by cutting through the semiconductor substrate 101 and any overlying materials in the singulation lanes 102. The microelectronic device 100 may be singulated using a saw process, a mechanical scribe process, or a laser scribe process, by way of example. Removing the III-N semiconductor layer 103 from the singulation lanes 102 may advantageously facilitate singulating the microelectronic device 100, due to the mechanical hardness of III-N semiconductor material in the III-N semiconductor layer 103.

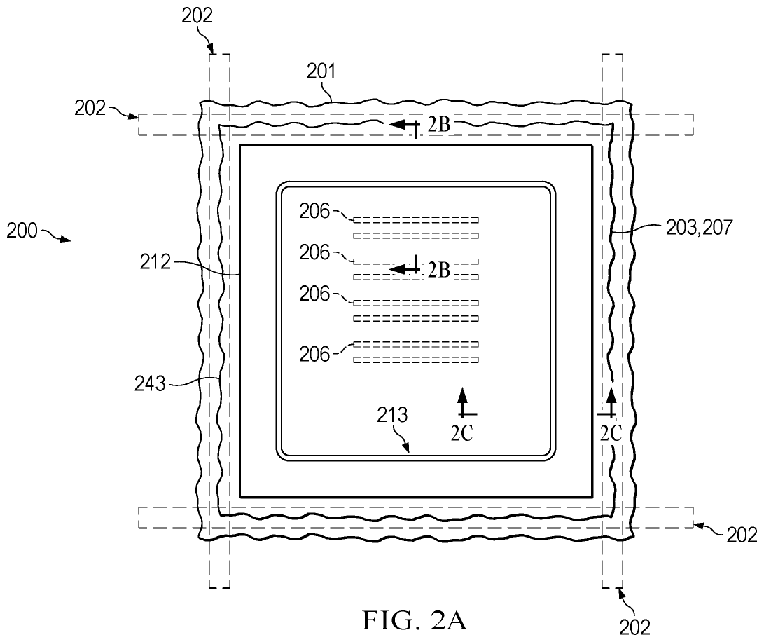

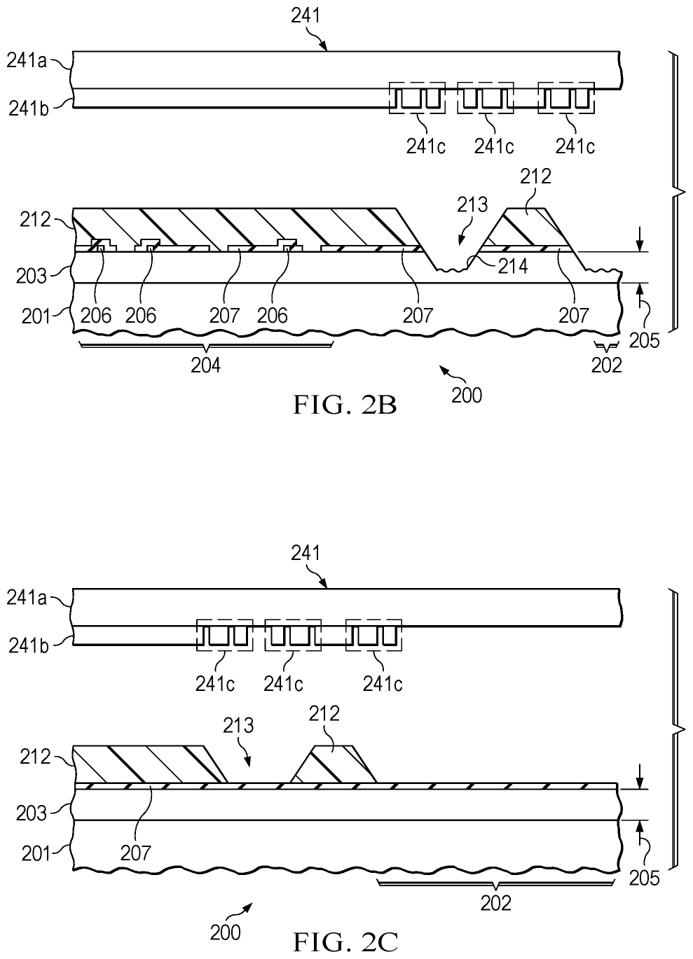

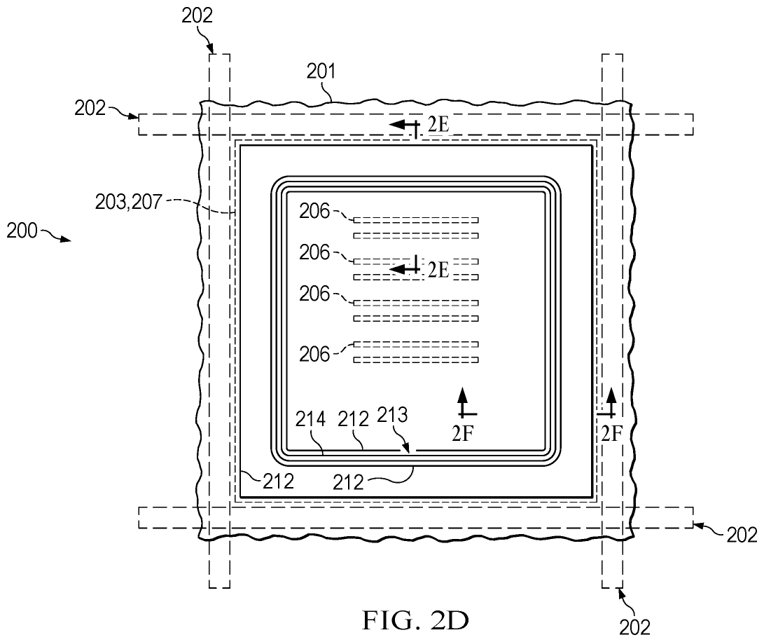

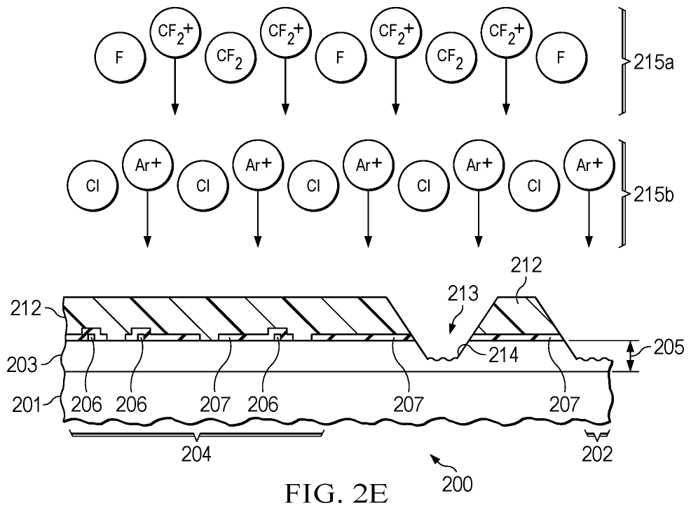

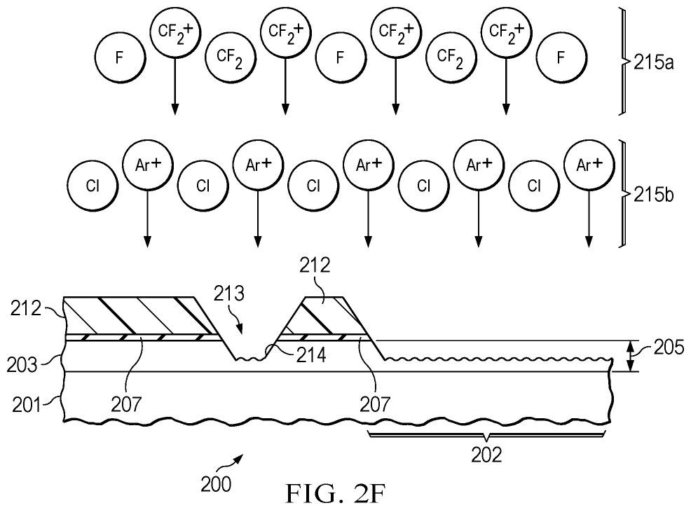

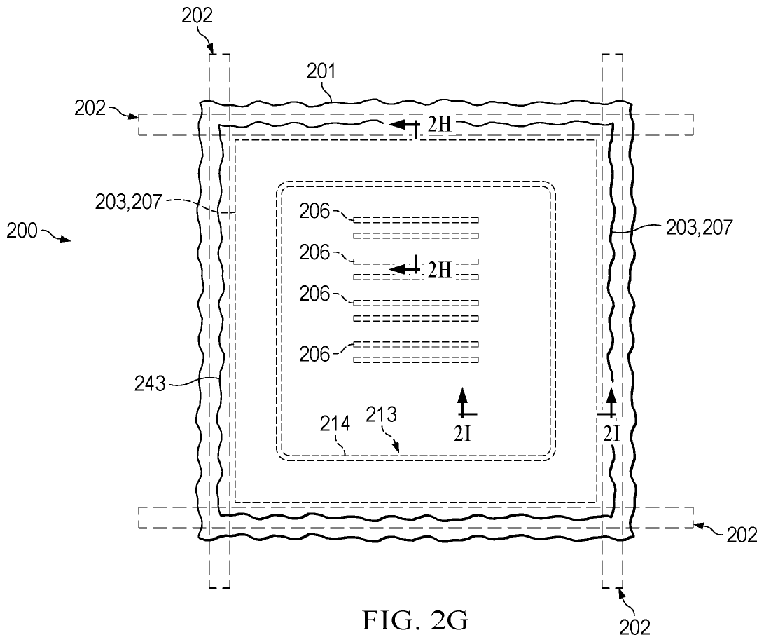

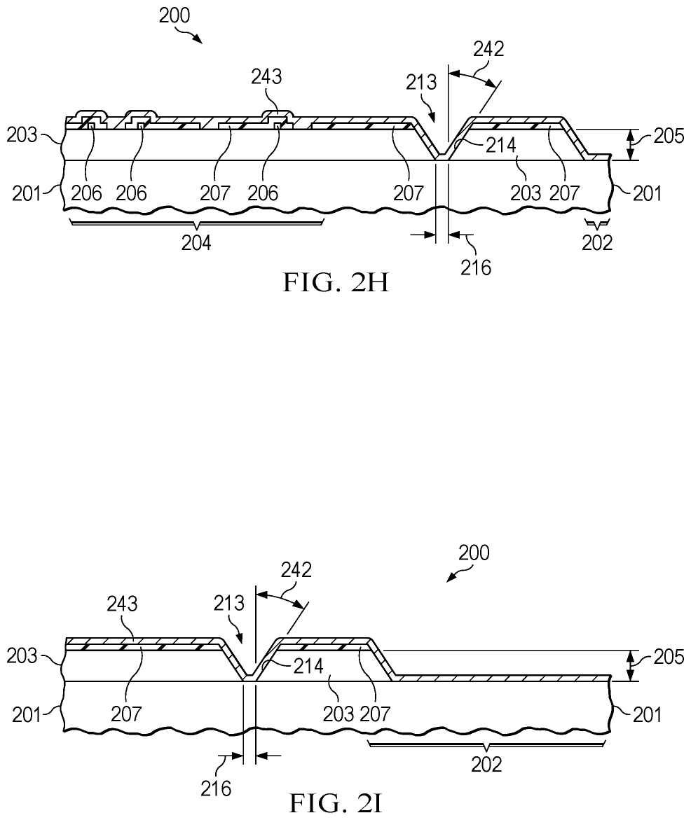

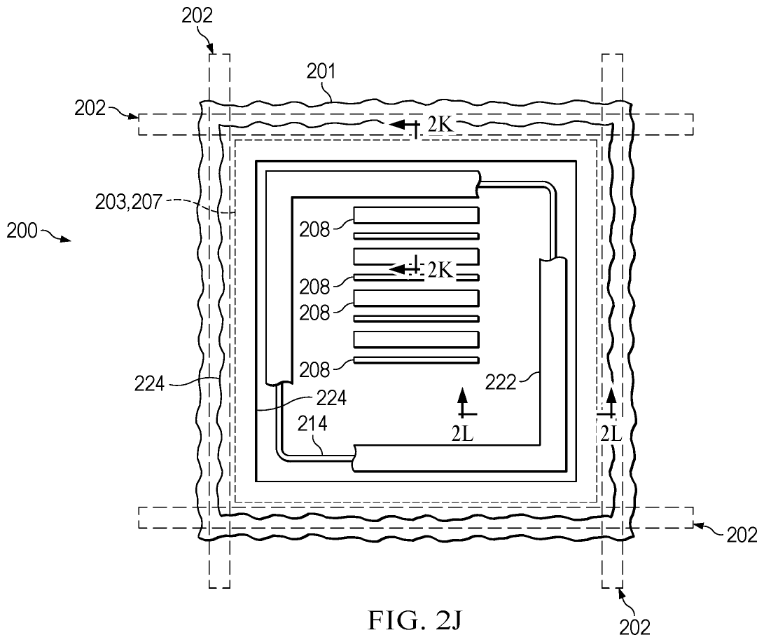

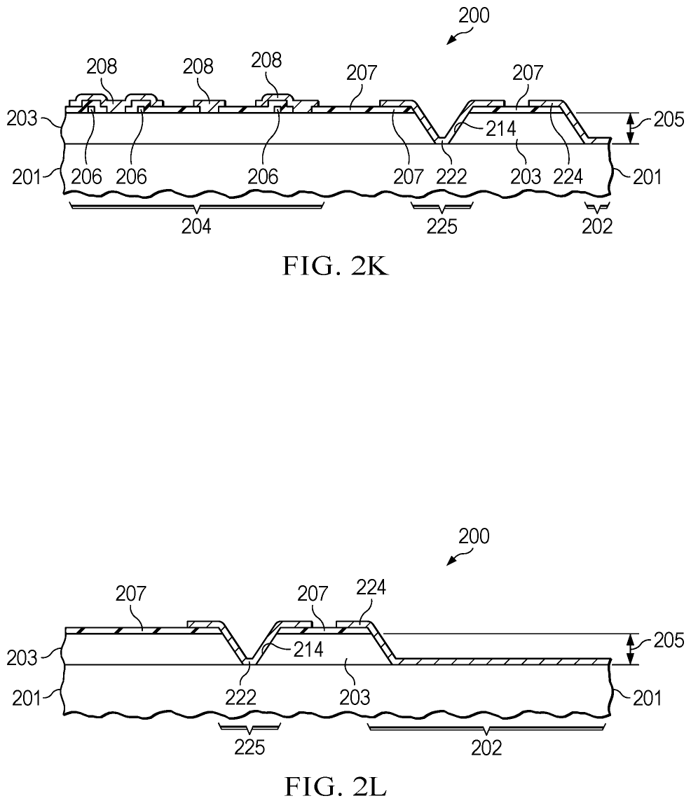

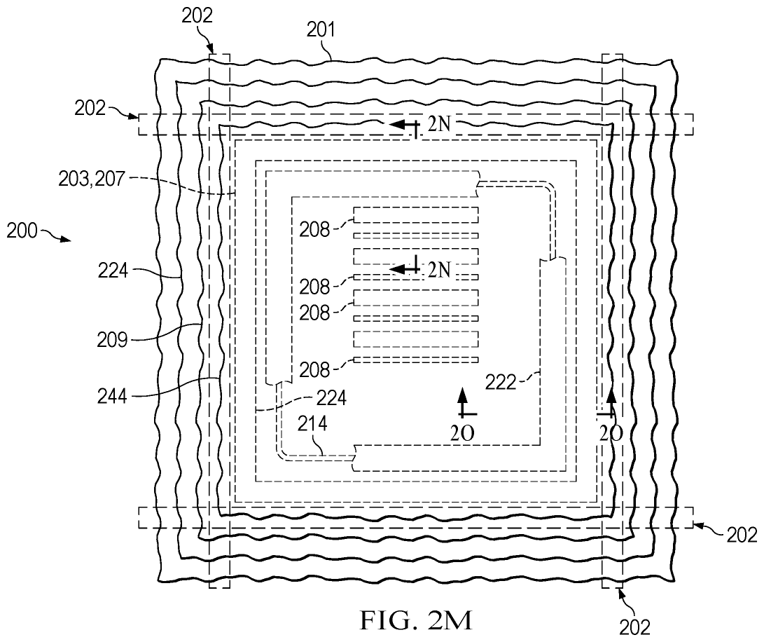

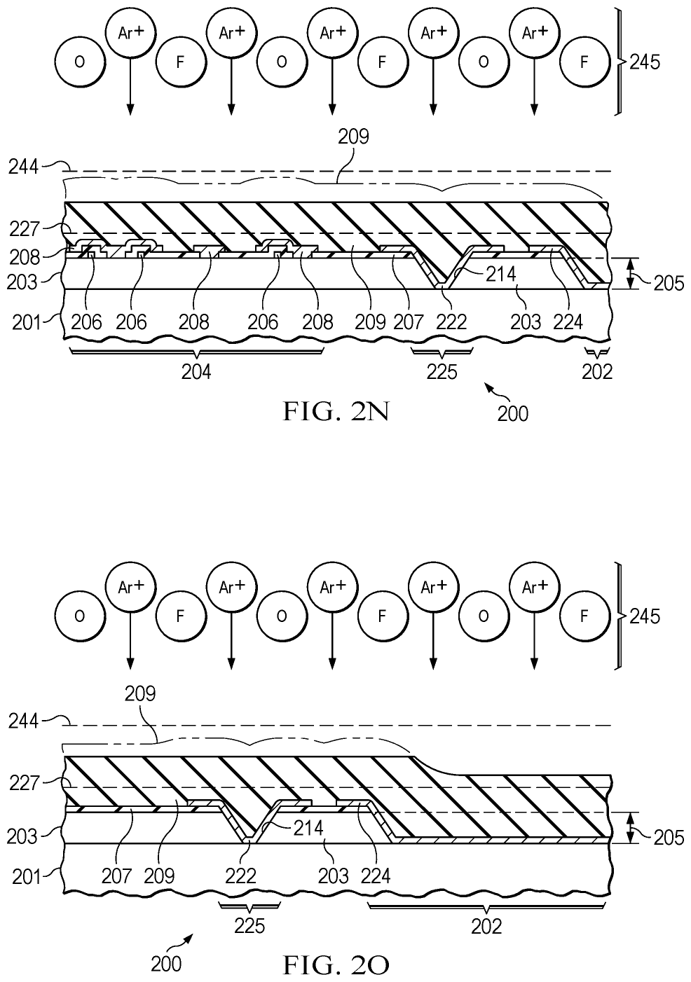

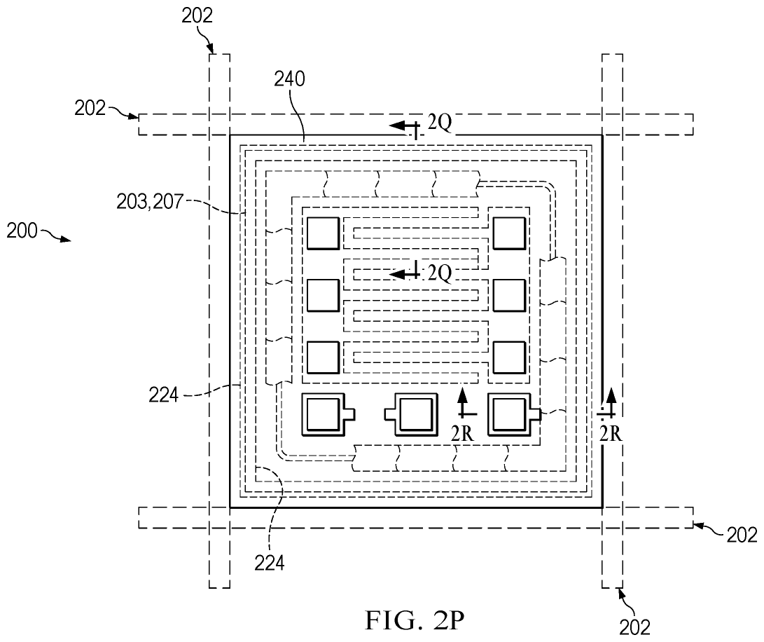

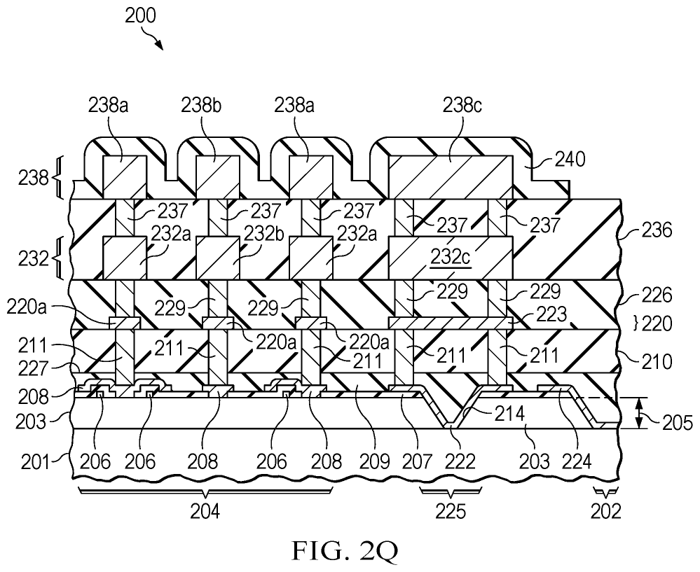

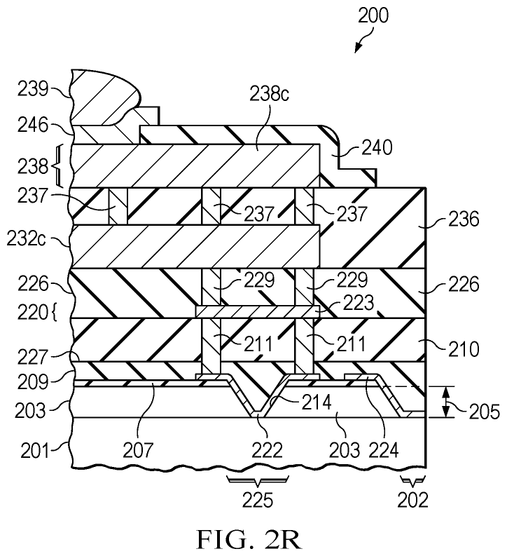

FIG. 2A through FIG. 2R are top views and cross sections of a microelectronic device having a substrate contact through a III-N semiconductor layer to a semiconductor substrate, depicted in successive stages of an example method of formation. FIG. 2A is a top view of the microelectronic device 200 at a first stage of formation, and FIG. 2B and FIG. 2C are cross sections of the microelectronic device 200 of FIG. 2A. Referring to FIG. 2A through FIG. 2C, the microelectronic device 200 is formed on the semiconductor substrate 201. The semiconductor substrate 201 may be manifested as any of the examples disclosed for the semiconductor substrate 101 of FIG. 1A through FIG. 1AB. The semiconductor substrate 201 may include additional microelectronic devices, not specifically shown, separated from the microelectronic device 200 by singulation lanes 202.

The microelectronic device 200 includes a III-N semiconductor layer 203 over the semiconductor substrate 201, extending across the microelectronic device 200 and across the singulation lanes 202. The III-N semiconductor layer 203 includes III-N semiconductor material, for example, in sublayers of varying composition, as disclosed in reference to the III-N semiconductor layer 203 of FIG. 1A through FIG. 1AB. A thickness 205 of the III-N semiconductor layer 203 may be 1 micron to 5 microns, by way of example.

In this example, the microelectronic device 200 includes an active component 204, depicted as a GaN FET 204 formed in and on the III-N semiconductor layer 203. Other active components are within the scope of this example. A gate structure 206 of the GaN FET 204 is formed over the III-N semiconductor layer 203. A first PMD layer 207 is formed over the III-N semiconductor layer 203 and over the gate structure 206. The first PMD layer 207 may include primarily silicon nitride, formed by an LPCVD process.

A substrate via etch mask 212 is formed over the first PMD layer 207, exposing the first PMD layer 207 in a substrate via area 213 that surrounds the GaN FET 204, proximate to a perimeter of the microelectronic device 200. In this example, the substrate via etch mask 212 may expose the first PMD layer 207 in the singulation lanes 202, as shown in FIG. 2A through FIG. 2C. The substrate via etch mask 212 of this example includes photoresist, formed by a photolithographic process using a photomask 241 having a transmissive substrate 241a, such as fused quartz, and a masking layer 241b, such as chromium. The masking layer 241b is patterned, with open areas corresponding to the substrate via area 213 and the singulation lanes 202. The photolithographic process may be a projection system having a reduction factor, so that features on the photomask 241 are larger than corresponding features projected onto the photoresist in the substrate via etch mask 212. The reduction factor may be 4 or 5, by way of example, so that the features on the photomask 241 are 4 or 5 times larger than the corresponding features projected onto the photoresist in the substrate via etch mask 212. The masking layer 241b has subresolution geometries 241c to provide a sloped profile in the substrate via etch mask 212. The subresolution geometries 241c may be larger than a wavelength of exposure light used in the photolithographic process, which may enable reliable reduced transmission of the exposure light through the photomask 241. The projected images of the subresolution geometries 241c may be smaller than the wavelength of the exposure light, providing a smoothed intensity profile that partially exposes the photoresist. The subresolution geometries 241c in this example are configured to expose the photoresist with sloped intensity profiles around the substrate via area 213 and the singulation lanes 202, providing a sloped profile in the photoresist after the photoresist is developed, as depicted in FIG. 2B and FIG. 2C.

FIG. 2D is a top view of the microelectronic device 200 at a subsequent stage of formation, and FIG. 2E and FIG. 2F are cross sections of the microelectronic device 200 of FIG. 2D. Referring to FIG. 2D through FIG. 2F, the first PMD layer 207 and the III-N semiconductor layer 203 are removed in the substrate via area 213 to form a substrate via opening 214, and in the singulation lanes 202. The first PMD layer 207 may be removed by a first RIE process 215a using one or more halogen etchant species, as disclosed in reference to the first RIE process 115a of FIG. 1E through FIG. 1H. The III-N semiconductor layer 203 is removed by a second RIE process 215b that erodes the substrate via etch mask 212 as the III-N semiconductor layer 203 is removed, so that the sloped profile of the substrate via etch mask 212 is replicated in a sidewall profile of the substrate via opening 214 at the substrate via area 213 and the singulation lanes 202. The second RIE process 215b may use a chemical etchant species and a physical etchant species, as disclosed in reference to the second RIE process 115b of FIG. 1E through FIG. 1H. The substrate via etch mask 212 may be eroded at a desired rate by adjusting an oxygen content in the second RIE process 215b. FIG. 2E and FIG. 2F depict the second RIE process 215b partway to completion. After the second RIE process 215b is completed, the singulation lanes 202 are free of the III-N semiconductor layer 203.

After the second RIE process 215b is completed, the substrate via etch mask 212 is removed. The substrate via etch mask 212 may be removed by any of the processes disclosed in reference to removal of the substrate via etch mask 112 of FIG. 1E through FIG. 1H.

FIG. 2G is a top view of the microelectronic device 200 at a subsequent stage of formation, and FIG. 2H and FIG. 2I are cross sections of the microelectronic device 200 of FIG. 2G. Referring to FIG. 2G through FIG. 2I, the substrate via opening 214 May have a width 216 at the semiconductor substrate 201 that is less than two times the thickness 205 of the III-N semiconductor layer 203, which may advantageously reduce an area of the microelectronic device 200 compared to a similar microelectronic device having a wider substrate via opening. In other versions, the width 216 of the substrate via openings 214 may be greater than two times the thickness 205 of the III-N semiconductor layer 203. In this example, the substrate via opening 214 may have sloped sides having a sidewall angle 242 greater than 15 degrees from vertical. In other versions of this example, the substrate via opening 214 may have sloped sides having the sidewall angle 242 less than 15 degrees from vertical.

Source and drain openings are formed through the first PMD layer 207 to expose the III-N semiconductor layer 203 in source and drain areas of the GaN FET 204. A source/drain metal layer 243 is formed over the first PMD layer 207, extending into the source and drain openings to make electrical connections to the source and drain areas, extending into the substrate via opening 214 to make an electrical connection to the semiconductor substrate 201 in the substrate via area 213, and extending into the singulation lanes 202. A thickness of the source/drain metal layer 243 is less than the thickness 205 of the III-N semiconductor layer 203. The thickness of the source/drain metal layer 243 may be less than 1 micron, to advantageously facilitate planarization of subsequent dielectric layers. The sidewall angle 242 greater than 15 degrees of the substrate via opening 214 may advantageously enable the source/drain metal layer 243 to provide a low resistance from a top surface of the first PMD layer 207 to the semiconductor substrate 201 in the substrate via area 213 while forming the source/drain metal layer 243 with physical deposition processes such as sputter processes, having semi-conformal deposition characteristics. The source/drain metal layer 243 may have a layer structure and composition similar to the source/drain pads 108 of FIG. 1A through FIG. 1D. Other sublayers and compositions for the source/drain metal layer 243 are within the scope of this example.

FIG. 2J is a top view of the microelectronic device 200 at a subsequent stage of formation, and FIG. 2K and FIG. 2L are cross sections of the microelectronic device 200 of FIG. 2J. Referring to FIG. 2J through FIG. 2L, the source/drain metal layer 243 of 2G through FIG. 2I is patterned, using an etch mask and RIE process, not specifically shown, to form source/drain pads 208 extending into the source and drain openings and making electrical connections to the source and drain areas, a substrate contact pad 222 extending into the substrate via opening 214 and making an electrical connection to the semiconductor substrate 201, and a singulation lane seal 224 extending into the singulation lanes 202. In some versions of this example, the substrate contact pad 222 may be separate from the singulation lane seal 224, as depicted in FIG. 2J through FIG. 2L. In other versions, the substrate contact pad 222 may be continuous with the singulation lane seal 224. A combination of the substrate via opening 214 and the substrate contact pad 222 extending into the substrate via opening 214 and making an electrical connection to the semiconductor substrate 201 provides a substrate via 225 of the microelectronic device 200. In this example, the substrate contact pad 222 extends above the III-N semiconductor layer 203 adjacent to the substrate via opening 214.

In this example, the substrate via 225 surrounds the GaN FET 204, proximate to a perimeter of the microelectronic device 200.

FIG. 2M is a top view of the microelectronic device 200 at a subsequent stage of formation, and FIG. 2N and FIG. 2O are cross sections of the microelectronic device 200 of FIG. 2M. Referring to FIG. 2M through FIG. 2O, a second PMD layer 209 is formed over the first PMD layer 207 and over the source/drain pads 208, the substrate contact pad 222, and the singulation lane seal 224. The second PMD layer 209 may include primarily silicon dioxide, and may be formed by a PECVD process to maintain the temperature of the microelectronic device 200 below the temperature that would degrade the main sublayer of the source/drain pads 208, the substrate contact pad 222, and the singulation lane seal 224. The second PMD layer 209 may include a sublayer of silicon nitride to reduce moisture infiltration into the area of the GaN FET 204 from the singulation lanes 202. The second PMD layer 209 may be sufficiently thick to provide dielectric isolation between source and drain potentials, and to reduce capacitive coupling, during operation of the microelectronic device 200. By way of example, the second PMD layer 209 may be 1 micron to 2 microns thicker than the thickness 205 of the III-N semiconductor layer 203, to completely fill the substrate via opening 214 and the singulation lanes 202. The second PMD layer 209 may be partially conformal, so that a top surface of the second PMD layer 209 is not planar after being formed.

The second PMD layer 209 is subsequently planarized. In this example, the second PMD layer 209 may be planarized by an etchback process. A planarizing layer 244 having a planar top surface is formed over the second PMD layer 209. The planarizing layer 244 may include an organic material such as polyisoprene or novolac resin, or may include an organo-silicate glass such as hydrogen silsesquioxane (HSQ). The planarizing layer 244 may be formed by a spin-on process, and is formed to have a planar top surface.

The planarizing layer 244 and a portion of the underlying second PMD layer 209 is removed by a planarizing plasma etch process 245, to planarize the underlying second PMD layer 209. The planarizing plasma etch process 245 etches the planarizing layer 244 and the second PMD layer 209 at sufficiently equal rates to transfer the planarity of the top surface of the planarizing layer 244 to the second PMD layer 209. The planarizing plasma etch process 245 may include fluorine radicals, oxygen radicals, and argon ions, as depicted schematically in FIG. 2N and FIG. 2O. FIG. 2M through FIG. 2O depict the planarizing plasma etch process 245 partway to completion. The dashed lines in FIG. 2M through FIG. 2O depict the planarizing layer 244 and the second PMD layer 209 at the beginning of the planarizing plasma etch process 245. The planarizing plasma etch process 245 is continued until a planar top surface 227, indicated by the dashed line in FIG. 2N and FIG. 2O, of the second PMD layer 209 is attained.

FIG. 2P is a top view of the microelectronic device 200 at a subsequent stage of formation, and FIG. 2Q and FIG. 2R are cross sections of the microelectronic device 200 of FIG. 2P. Referring to FIG. 2Q through FIG. 2R, planarization of the second PMD layer 209, disclosed in reference to FIG. 2M through FIG. 2O, provides the planar top surface 227 of the second PMD layer 209.

A third PMD layer 210 is formed over the second PMD layer 209. The third PMD layer 210 may include primarily silicon dioxide, and may be formed by a PECVD process. The third PMD layer 210 may be sufficiently thick to reduce capacitive coupling, during operation of the microelectronic device 200. By way of example, the third PMD layer 210 may be 1 micron to 5 microns thick.

Contacts 211 are formed through the third PMD layer 210 and the second PMD layer 209 to make electrical connections to the source/drain pads 208 and the substrate contact pad 222. The contacts 211 may be formed by etching contact holes through the third PMD layer 210 and the second PMD layer 209 to expose portions of the source/drain pads 208 and the substrate contact pad 222. The contacts 211 may have a structure and composition similar to the contacts 111 of FIG. 1A through FIG. 1D, and may be formed by a similar process. Alternatively, the contacts 211 may have a different structure and composition, for example the contacts 211 may include cobalt, and may be formed by a different process, such as selective deposition.

A pad interconnect layer 220, including source pads 220a, drain pads 220b, and a lower scribe seal pad 223 is formed over the third PMD layer 210, making electrical connections to the contacts 211. The members of the pad interconnect layer 220 may have a structure and composition similar to the members of the pad interconnect layer 120 of FIG. 1I through FIG. 1L, and may be formed by a similar process sequence. Alternatively, the members of the pad interconnect layer 220 may have a different structure and composition, such as a damascene structure and including copper, and may be formed by a different process, such as a copper single damascene process.

A first ILD layer 226 is formed over the third PMD layer 210, the members of the pad interconnect layer 220, and extending into the singulation lanes 202. The first ILD layer 226 may include primarily silicon dioxide, and may be formed by a PECVD process. The first ILD layer 226 may be planarized to facilitate subsequent photolithography processes. By way of example, the first ILD layer 226 may be 1 micron to 5 microns thick.

First vias 229 are formed through the first ILD layer 226 to make electrical connections to the members of the pad interconnect layer 220. The first vias 229 may have a composition and a structure similar to the first vias 129 of FIG. 1U through FIG. 1X, and may be formed by a similar process sequence. Other compositions and structures for the first vias 229, such as copper vias on a barrier liner, formed by a copper damascene process, are within the scope of this example.

A first interconnect level 232 is formed on the first ILD layer 226, making electrical connections to the first vias 229. The first interconnect level 232 includes first source interconnects 232a, first drain interconnects 232b, and a first substrate interconnect 232c. Members of the first interconnect level 232 may have a sublayer structure and composition similar to the first interconnect level 132 of FIG. 1Y through FIG. 1AB. Other sublayer structures and compositions for the first interconnect level 232 are within the scope of this example. The first interconnect level 232 may be 3 microns to 5 micron thick, by way of example, to provide low resistance to lateral currents between the GaN FET 204 and input/output terminals of the microelectronic device 200. The first interconnect level 232 may have linewidths and spaces proximate to the substrate via opening 214 that are less than the thickness 205 of the III-N semiconductor layer 203, resulting from the planarity of the planar top surface 227 of the second PMD layer 209, accruing the advantage of reduced area for the microelectronic device 200.

A second ILD layer 236 may be formed over the first ILD layer 226 and the first interconnect level 232. The second ILD layer 236 may include primarily silicon dioxide, and may be formed by a PECVD process. The second ILD layer 236 may be 1 micron to 5 microns thick, by way of example. The second ILD layer 236 may be planarized to facilitate subsequent photolithography processes.

Second vias 237 may be formed through the second ILD layer 236 to make electrical connections to the members of the first interconnect level 232. The second vias 237 may have a composition and a structure similar to the first vias 229, and may be formed by a similar process sequence. Other compositions and structures for the second vias 237 are within the scope of this example.

A second interconnect level 238 may be formed on the second ILD layer 236, making electrical connections to the second vias 237. The second interconnect level 238 may have a layer structure and composition similar to the first interconnect level 232, and may be formed by a similar process sequence. The second interconnect level 238 may include a main sublayer 3 microns to 5 micron thick, by way of example, to provide low resistance to lateral currents between the GaN FET 204 and input/output terminals of the microelectronic device 200. Members of the second interconnect level 238 include second source interconnects 238a, second drain interconnects 238b, and a second substrate interconnect 238c. The second interconnect level 238 may have linewidths and spaces proximate to one or more of the substrate via openings 214 that are less than the thickness 205 of the III-N semiconductor layer 203, similar to the first interconnect level 232, resulting from the planarity of the planar top surface 227 of the first ILD layer 226, accruing the advantage of enabling a reduced area of the microelectronic device 200.

A PO layer 240 may be formed over the second ILD layer 236 and the second interconnect level 238, with openings for input/output terminals 239. The PO layer 240 may include polyimide, silicon dioxide, silicon nitride, silicon oxynitride, or any combination thereof. An under bump metal (UBM) 246 may be formed on members of the second interconnect level 238, where exposed by the PO layer 240. The UBM 246 may include an adhesion sublayer of titanium or titanium tungsten, and a bond sublayer of nickel, palladium, or copper on the adhesion sublayer. The UBM 246 may be formed by plating on a seed layer through a plating mask, by electroless plating, or other method. Input/output terminals 239 are formed, making electrical connections to the second interconnect level 238. The input/output terminals 239 may be manifested as solder bumps 239, as depicted in FIG. 2R. The planar top surface 227 of the second PMD layer 209 may provide planarity for the second interconnect level 238, which may provide uniform thicknesses for bump bonds formed from the solder bumps 239, advantageously increasing reliability of the bump bonds. Alternatively, the input/output terminals 239 may be manifested as wire bond pads, copper pillars, or other terminal configuration.

The microelectronic device 200 is subsequently singulated by cutting through the semiconductor substrate 201 and any overlying materials in the singulation lanes 202. Removing the III-N semiconductor layer 203 from the singulation lanes 202 may accrue the advantage of facilitating singulation of the microelectronic device 200.

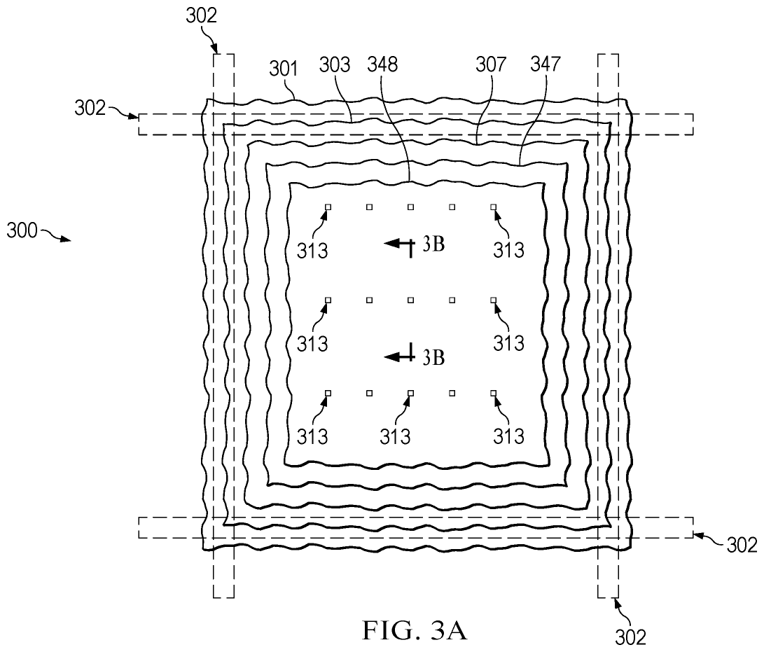

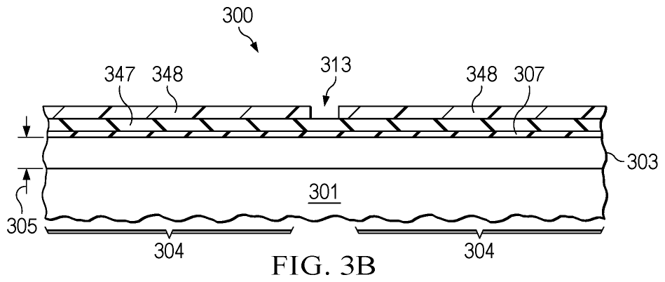

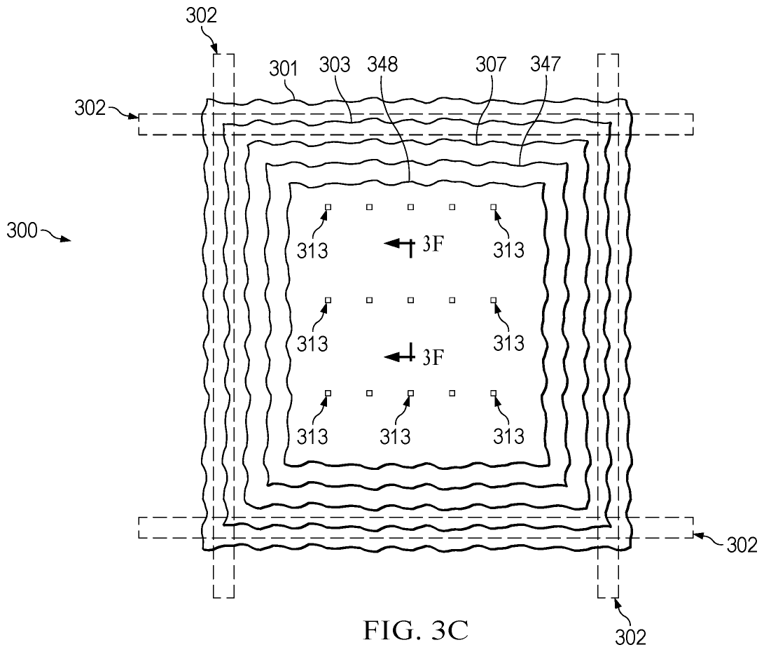

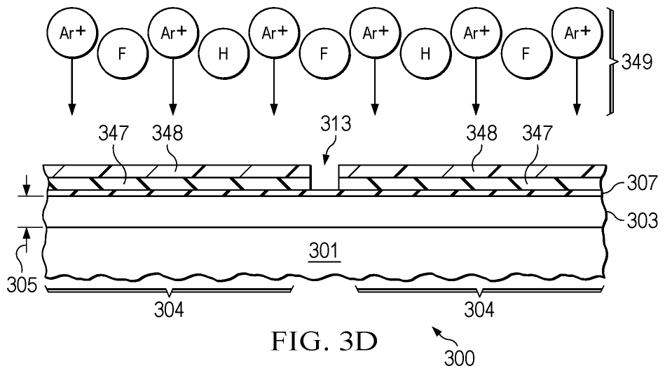

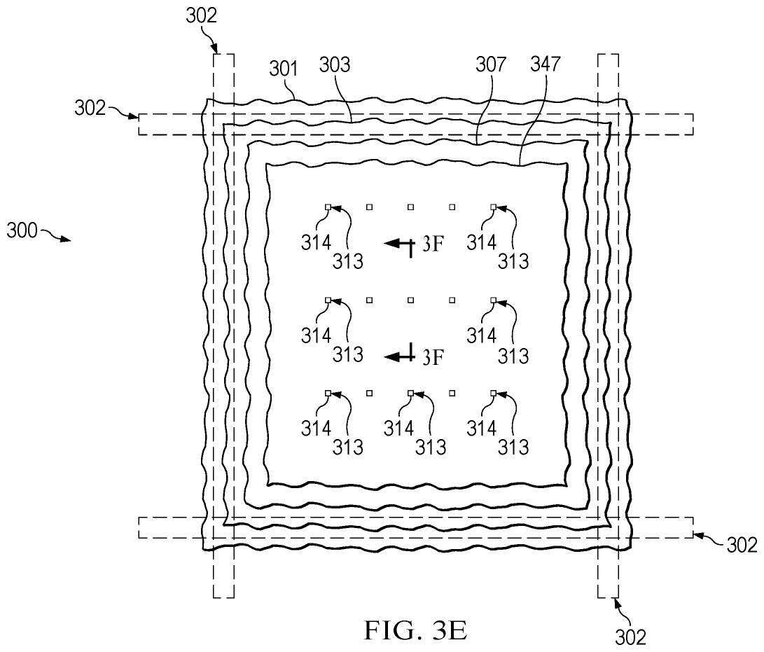

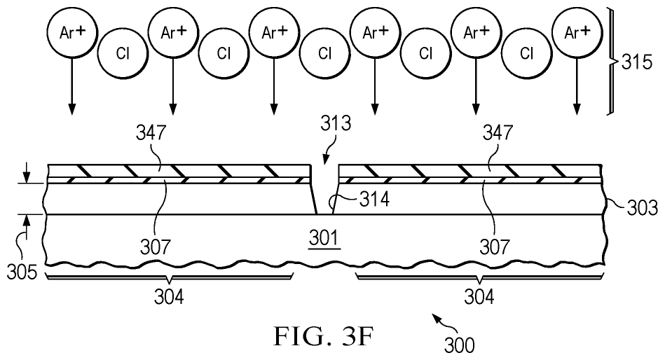

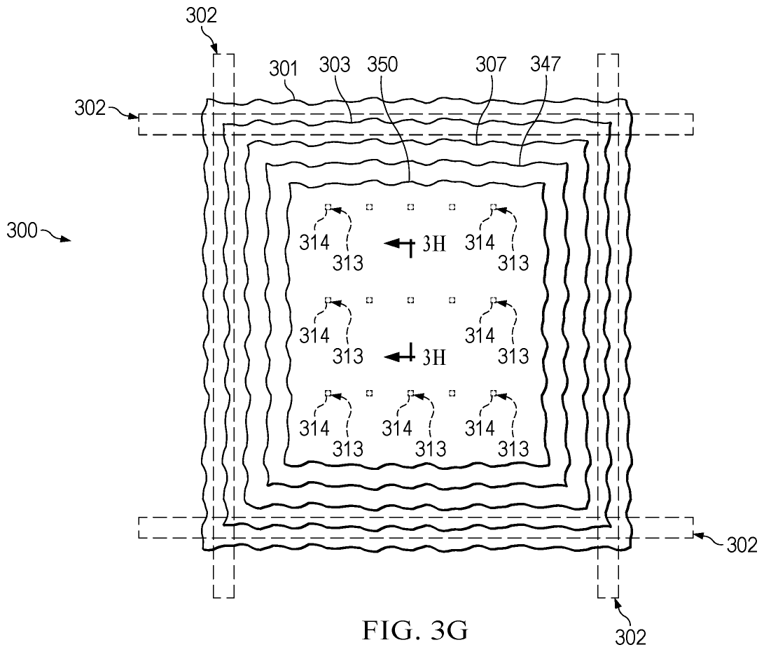

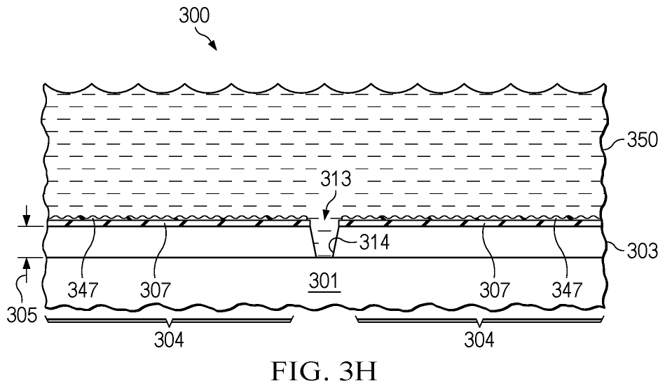

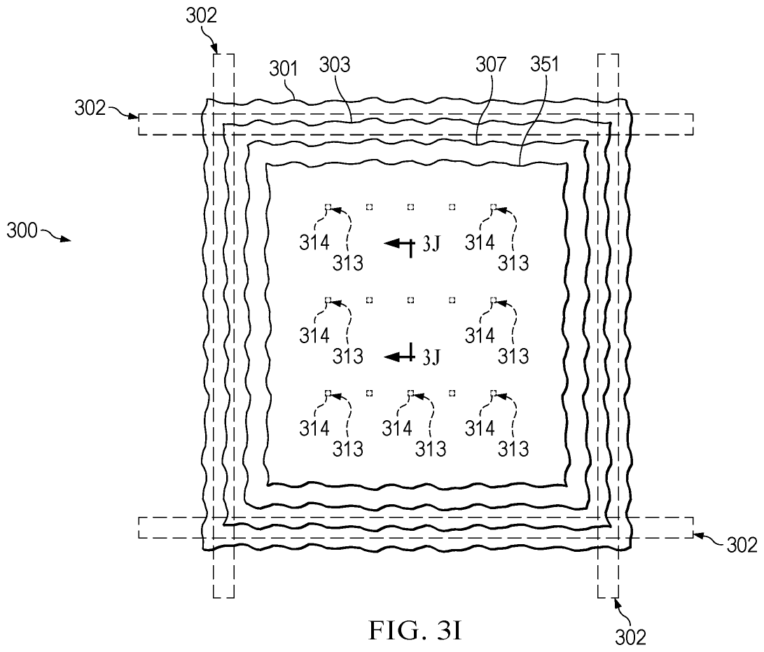

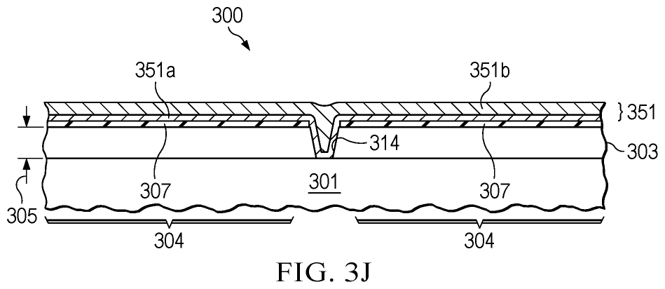

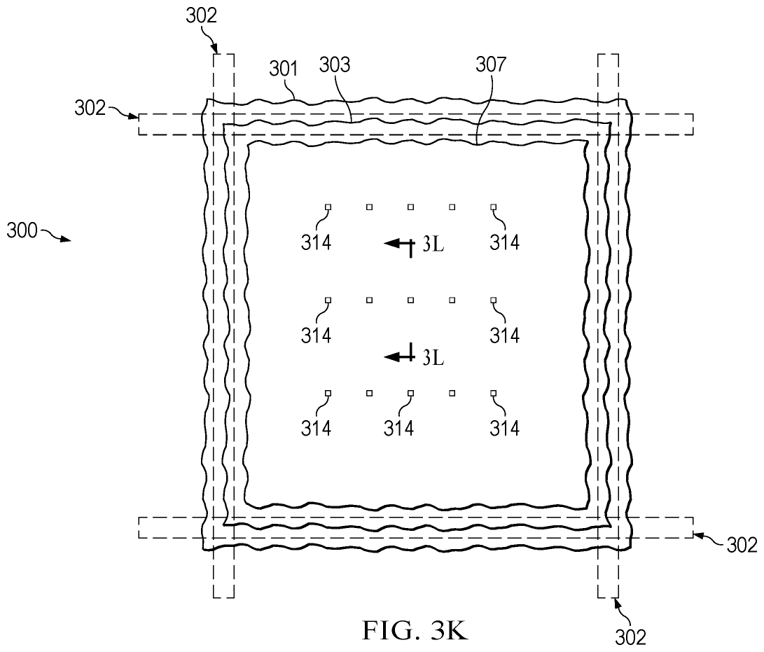

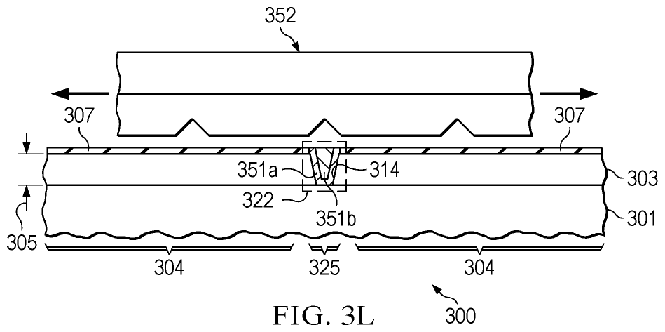

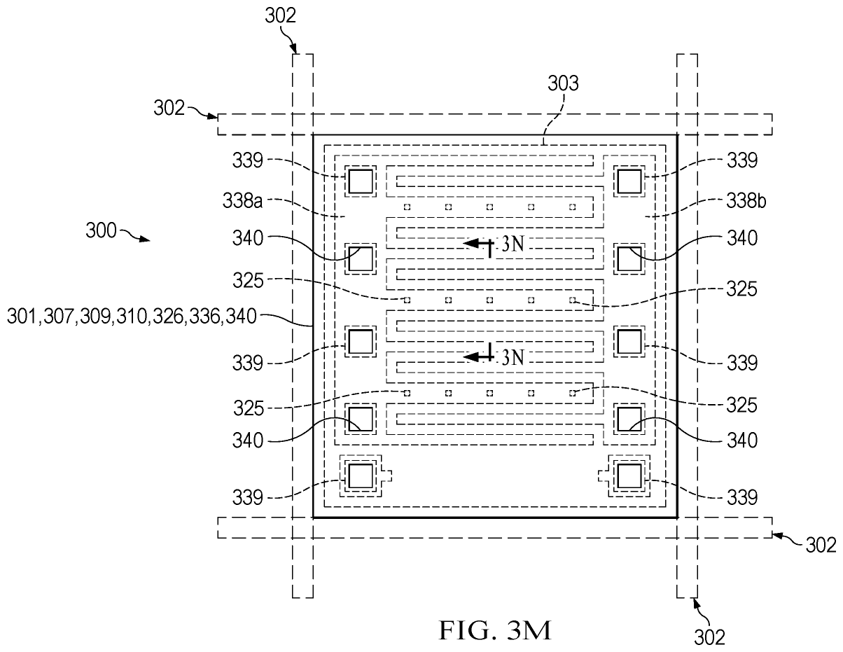

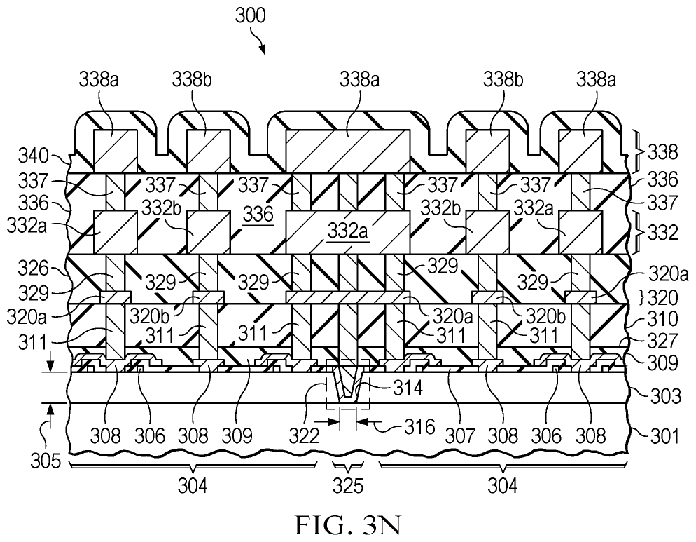

FIG. 3A through FIG. 3N are top views and cross sections of a microelectronic device having a substrate contact through a III-N semiconductor layer to a semiconductor substrate, depicted in successive stages of an example method of formation. FIG. 3A is a top view of the microelectronic device 300 at a first stage of formation, and FIG. 3B is a cross section of the microelectronic device 300 of FIG. 3A. Referring to FIG. 3A and FIG. 3B, the microelectronic device 300 is formed on the semiconductor substrate 301. The semiconductor substrate 301 may be manifested as any of the examples disclosed for the semiconductor substrate 101 of FIG. 1A through FIG. 1AB. The semiconductor substrate 301 may include additional microelectronic devices, not specifically shown, separated from the microelectronic device 300 by singulation lanes 302.

The microelectronic device 300 includes a III-N semiconductor layer 303 over the semiconductor substrate 301, extending across the microelectronic device 300. The III-N semiconductor layer 303 includes III-N semiconductor material, for example, in sublayers of varying composition, as disclosed in reference to the III-N semiconductor layer 103 of FIG. 1A through FIG. 1AB. A thickness 305 of the III-N semiconductor layer 303 may be 1 micron to 5 microns, by way of example.

In this example, the microelectronic device 300 includes an active component 304, depicted as a GaN FET 304 formed in and on the III-N semiconductor layer 303. Other active components are within the scope of this example. A gate structure 306 of the GaN FET 304, shown in FIG. 3N, is formed over the III-N semiconductor layer 303.

A first PMD layer 307 is formed over the III-N semiconductor layer 303 and over the gate structure 306. The first PMD layer 307 may include primarily silicon nitride, formed by an LPCVD process. In this example, the first PMD layer 307 is sufficiently thick to provide a polish stop layer for a tungsten CMP process. The first PMD layer 307 may be 50 nanometers to 150 nanometers thick, by way of example.

A hard mask layer 347 is formed over the first PMD layer 307. The hard mask layer 347 includes inorganic material which can be removed by a wet etch process without degrading the first PMD layer 307 or the III-N semiconductor layer 303. The hard mask layer 347 may include silicon dioxide, for example, and may be formed by an LPCVD process using dichlorosilane and nitrous oxide, or a chemical vapor deposition (CVD) process using tetraethyl orthosilicate (TEOS), formally named tetraethoxysilane. The hard mask layer 347 is sufficiently thick to provide a hard mask for etching through the III-N semiconductor layer 303; a thickness of the hard mask layer 347 may be 33 percent to 100 percent of the thickness 305 of the III-N semiconductor layer 303, by way of example.

A sacrificial etch mask 348 is formed over the hard mask layer 347, exposing the hard mask layer 347 in substrate via areas 313. The sacrificial etch mask 348 may include photoresist, formed by a photolithographic process. In this example, the substrate via areas 313 may be spatially distributed in the microelectronic device 300, as depicted in FIG. 3A.

FIG. 3C is a top view of the microelectronic device 300 at a subsequent stage of formation, and FIG. 3D is a cross section of the microelectronic device 300 of FIG. 3C. Referring to FIG. 3C and FIG. 3D, the hard mask layer 347 is removed in the substrate via areas 313 using a hard mask RIE process 349. The hard mask RIE process 349 may use fluorine radicals, as indicated schematically in FIG. 3D. A portion or all of the first PMD layer 307 may be removed by the hard mask RIE process 349.

After the hard mask layer 347 is removed in the substrate via areas 313, the sacrificial etch mask 348 is removed. The sacrificial etch mask 348 may be removed by an oxygen plasma process, a wet strip process, or a combination of both.

FIG. 3E is a top view of the microelectronic device 300 at a subsequent stage of formation, and FIG. 3F is a cross section of the microelectronic device 300 of FIG. 3E. Referring to FIG. 3E and FIG. 3F, any remaining portion of the first PMD layer 307 and all of the III-N semiconductor layer 303 are removed in the substrate via areas 313, where exposed by the hard mask layer 347, to form substrate via openings 314. The III-N semiconductor layer 303 is removed by a III-N RIE process 315, which may be similar to the second RIE process 115b of FIG. 1F through FIG. 1H. The semiconductor substrate 301 is exposed when the III-N RIE process 315 is completed.

In some versions of this example, the III-N semiconductor layer 303 may be removed from the singulation lanes 302 by a separate etch process from the III-N RIE process 315. The III-N semiconductor layer 303 may be removed from the singulation lanes 302 prior to forming the substrate via openings 314, or after forming the substrate via openings 314.

FIG. 3G is a top view of the microelectronic device 300 at a subsequent stage of formation, and FIG. 3H is a cross section of the microelectronic device 300 of FIG. 3G. Referring to FIG. 3G and FIG. 3H, the hard mask layer 347 is removed. The hard mask layer 347 may be removed by a wet etch process 350 including a dilute buffered aqueous solution of hydrofluoric acid, by way of example. Other methods of removing the hard mask layer 347 are within the scope of this example. The process to remove the hard mask layer 347 leaves sufficient material in the first PMD layer 307 to provide the polish stop layer for the tungsten CMP process.

FIG. 3I is a top view of the microelectronic device 300 at a subsequent stage of formation, and FIG. 3J is a cross section of the microelectronic device 300 of FIG. 3I. Referring to FIG. 3I and FIG. 3J, a substrate contact layer stack 351 is formed over the first PMD layer 307, extending into the substrate via openings 314 to form electrical connections to the semiconductor substrate 301. The substrate contact layer stack 351 may include an adhesion sublayer 351a including titanium, contacting the first PMD layer 307, the III-N semiconductor layer 303, and the semiconductor substrate 301. The adhesion sublayer 351a may be formed by a sputter process, by way of example. The substrate contact layer stack 351 may include a fill layer 351b including tungsten on the adhesion sublayer 351a, filling the substrate via openings 314 and extending over the first PMD layer 307. The fill layer 351b may be formed by an MOCVD process using tungsten hexafluoride.

FIG. 3K is a top view of the microelectronic device 300 at a subsequent stage of formation, and FIG. 3L is a cross section of the microelectronic device 300 of FIG. 3K. Referring to FIG. 3K and FIG. 3L, the fill layer 351b and the adhesion sublayer 351a are removed from over the first PMD layer 307, leaving the fill layer 351b and the adhesion sublayer 351a in the substrate via openings 314 to provide substrate contact pads 322. A combination of the substrate via openings 314 and the substrate contact pads 322 extending into the substrate via openings 314 and making electrical connections to the semiconductor substrate 301 provides substrate vias 325 of the microelectronic device 300. In this example, the substrate contact pads 322 fill the substrate via openings 314, and top surfaces of the substrate contact pads 322 are planar above the substrate via openings 314.

The fill layer 351b and the adhesion sublayer 351a may be removed from over the first PMD layer 307 using a tungsten CMP process 352, depicted schematically in FIG. 3L by a CMP pad. Alternatively, the fill layer 351b and the adhesion sublayer 351a may be removed using an etchback process. Removal of the fill layer 351b and the adhesion sublayer 351a leaves at least a portion of the first PMD layer 307 in place over the III-N semiconductor layer 303.

FIG. 3M is a top view of the microelectronic device 300 at a subsequent stage of formation, and FIG. 3N is a cross section of the microelectronic device 300 of FIG. 3M. Referring to FIG. 3M and FIG. 3N, in some versions of this example, the substrate via openings 314 may have a width 316 at the semiconductor substrate 301 that is less than two times the thickness 305 of the III-N semiconductor layer 303, accruing the advantage of reduced area for the microelectronic device 300.

Source/drain pads 308 are formed through the first PMD layer 307 to make electrical connections to source and drain regions of the GaN FET 304. The source/drain pads 308 may have a layer structure and composition similar to the source/drain pads 108 of FIG. 1A through FIG. 1D. Other sublayers and compositions for the source/drain pads 308 are within the scope of this example.

A second PMD layer 309 may be formed over the first PMD layer 307 and the source/drain pads 308. The second PMD layer 309 may include silicon nitride. The second PMD layer 309 is planarized to form a planar top surface 327 extending over the substrate vias 325.

A third PMD layer 310 may be formed over the second PMD layer 309. The third PMD layer 310 may include silicon dioxide. Alternatively a combined PMD layer, not specifically shown, including silicon nitride, silicon dioxide, or silicon oxynitride, providing the isolation and capacitance load of the second PMD layer 309 and the third PMD layer 310, may be formed over the first PMD layer 307 and the source/drain pads 308.

Contacts 311 are formed through the third PMD layer 310 and the second PMD layer 309 to make electrical connections to the source/drain pads 308 and the substrate vias 325. In this example, the substrate vias 325 may be directly electrically connected to source nodes of the GaN FET 304 through the source/drain pads 308, as depicted in FIG. 3N. The contacts 311 may include tungsten, aluminum, copper, or other electrically conductive material.

A pad interconnect layer 320 is formed over the third PMD layer 310 and the contacts 311. Members of the pad interconnect layer 320 in this example include source pads 320a and drain pads 320b, which make electrical connections to the source/drain pads 308 through the contacts 311. The members of the pad interconnect layer 320 may include primarily aluminum, primarily copper, or primarily another electrically conductive material.

A first ILD layer 326 is formed over the third PMD layer 310, the members of the pad interconnect layer 320, and extending into the singulation lanes 302. The first ILD layer 326 may include primarily silicon dioxide. First vias 329 are formed through the first ILD layer 326 to make electrical connections to the members of the pad interconnect layer 320.

A first interconnect level 332 is formed over the first ILD layer 326. The first interconnect level 332 includes first source interconnects 332a and first drain interconnects 332b which carry currents laterally from the GaN FET 304 to input/output terminals 339 of the microelectronic device 300. The members of the first interconnect level 332 may include primarily aluminum, primarily copper, or primarily another electrically conductive material.

A second ILD layer 336 may be formed over the first ILD layer 326 and the first interconnect level 332. The second ILD layer 336 may have a structure and composition similar to the first ILD layer 326. Second vias 337 may be formed through the second ILD layer 336 to make electrical connections to the members of the first interconnect level 332. A second interconnect level 338 may be formed over the second ILD layer 336. The second interconnect level 338 includes second source interconnects 338a and second drain interconnects 338b which also carry currents laterally from the GaN FET 304 to the input/output terminals 339 Members of the second interconnect level 338 may have a structure and composition similar to the members of the first interconnect level 332. The input/output terminals 339 are formed on the members of the second interconnect level 338. A PO layer 340 may be formed over the second ILD layer 336 and the second interconnect level 338, with openings over the input/output terminals 339. The microelectronic device 300 is subsequently singulated by cutting through the semiconductor substrate 301 and any overlying materials in the singulation lanes 302.

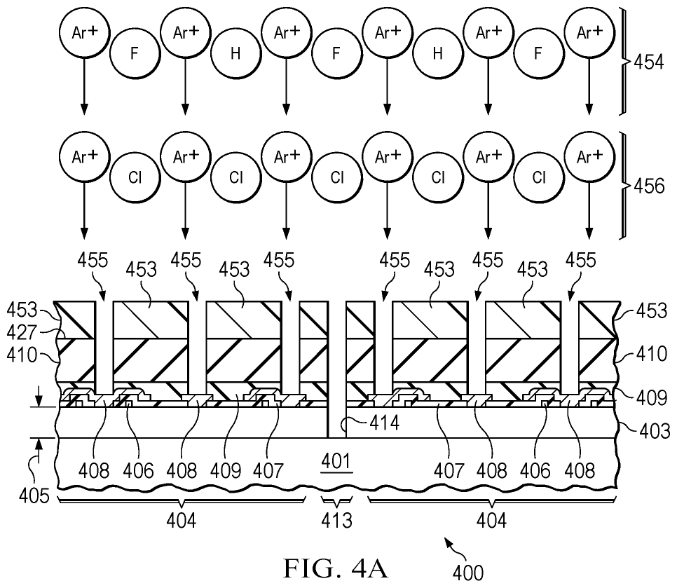

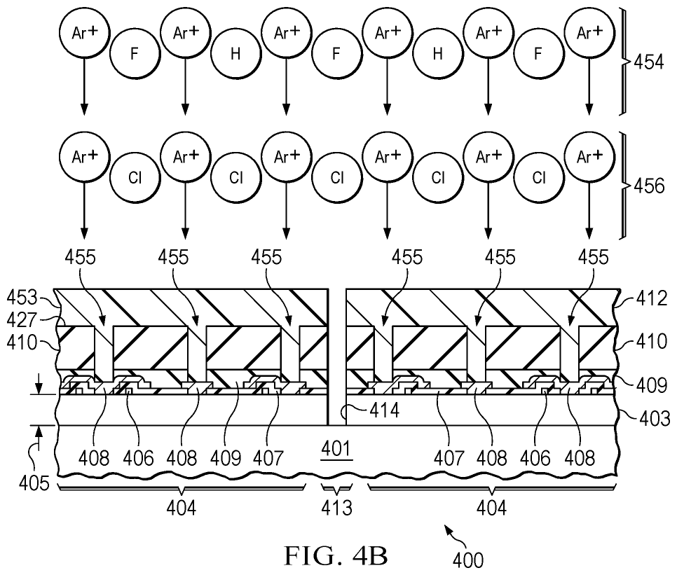

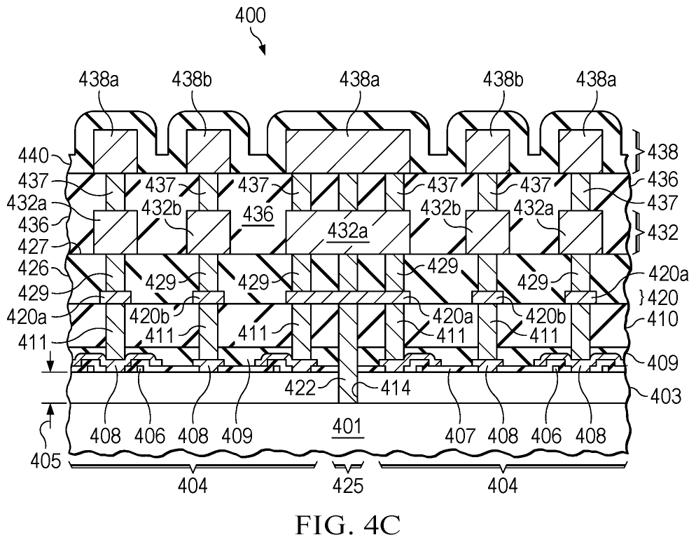

FIG. 4A through FIG. 4C are cross sections of a microelectronic device having a substrate contact through a III-N semiconductor layer to a semiconductor substrate, depicted in successive stages of example methods of formation. FIG. 4A depicts a first version for forming substrate via openings, and FIG. 4B depicts a second version for forming the substrate via openings. FIG. 4C depicts the completed microelectronic device.

Referring to FIG. 4A, the microelectronic device 400 is formed on the semiconductor substrate 401. The semiconductor substrate 401 may be manifested as any of the examples disclosed for the semiconductor substrate 101 of FIG. 1A through FIG. 1AB. The microelectronic device 400 includes a III-N semiconductor layer 403 over the semiconductor substrate 401, extending across the microelectronic device 400. The III-N semiconductor layer 403 includes III-N semiconductor material, for example, in sublayers of varying composition, as disclosed in reference to the III-N semiconductor layer 103 of FIG. 1A through FIG. 1AB. A thickness 405 of the III-N semiconductor layer 403 may be 1 micron to 5 microns, by way of example. In this example, the microelectronic device 400 includes an active component 404, depicted as a GaN FET 404 formed in and on the III-N semiconductor layer 403. Other active components are within the scope of this example. A gate structure 406 of the GaN FET 404 is formed over the III-N semiconductor layer 403.

A first PMD layer 407 is formed over the III-N semiconductor layer 403 and over the gate structure 406. The first PMD layer 407 may include primarily silicon nitride. Source/drain pads 408 are formed through the first PMD layer 407 to make electrical connections to source and drain regions of the GaN FET 404. A second PMD layer 409 may be formed over the first PMD layer 407 and the source/drain pads 408. The second PMD layer 409 may include silicon nitride. A third PMD layer 410 may be formed over the second PMD layer 409. The third PMD layer 410 may include silicon dioxide. The second PMD layer 409, the third PMD layer 410, or both is planarized to provide a planar top surface 427 of the third PMD layer 410, to facilitate a subsequent metal planarization process.

A contact etch mask 453 is formed over the third PMD layer 410, exposing the third PMD layer 410 in areas for contact holes 455 and in substrate via areas 413 for substrate via openings 414. The contact etch mask 453 may include organic material such as photoresist with anti-reflection material, or may include hard mask material such as amorphous carbon, or may include both organic material and hard mask material.

The third PMD layer 410 and the second PMD layer 409 are subsequently removed where exposed by the contact etch mask 453, using a first contact RIE process 454 with fluorine radicals, as depicted schematically in FIG. 4A, to form the contact holes 455 and upper portions of the substrate via openings 414. The first contact RIE process 454 may adjust flows of reactant gases when transitioning from etching the third PMD layer 410 to etching the second PMD layer 409.

The III-N semiconductor layer 403 is removed in the substrate via areas 413 by a second contact RIE process 456 to complete formation of the substrate via openings 414. The second contact RIE process 456 may use a chemical etchant species, depicted schematically as chlorine radicals, and a physical etchant species, depicted schematically as argon ions. The second contact RIE process 456 is continued until the semiconductor substrate 401 is exposed in the substrate via areas 413. In this version of forming the substrate via openings 414, the source/drain pads 408 may include an electrically conductive etch stop layer, not specifically shown, to reduce etching of the source/drain pads 408 during the second contact RIE process 456. The electrically conductive etch stop layer may include gold, platinum, or palladium, by way of example. Forming the substrate via openings 414 concurrently with the contact holes 455 may advantageously reduce fabrication time and cost of the microelectronic device 400.

The contact etch mask 453 is subsequently removed. Photoresist and anti-reflection material in the contact etch mask 453 may be removed by a wet strip process using NMP or an aqueous mixture of sulfuric acid and hydrogen peroxide. Amorphous carbon in the contact etch mask 453 may be removed by an oxygen plasma process. Formation of the microelectronic device 400 continues with FIG. 4C.

Referring to FIG. 4B, in this version of forming the substrate via openings 414, the microelectronic device 400 is formed as disclosed in reference to FIG. 4A, up through formation of the contact holes 455, with the exception that the substrate via openings 414 are not formed concurrently with the contact holes 455. In this version, the substrate via areas 413 are not exposed while the contact holes 455 are being formed. After the contact holes 455 are formed, a substrate via etch mask 412 is formed over the third PMD layer 410, exposing the third PMD layer 410 in the substrate via areas 413 for the substrate via openings 414. The third PMD layer 410 and the second PMD layer 409 are subsequently removed where exposed by the substrate via etch mask 412, using the first contact RIE process 454, and the III-N semiconductor layer 403 is removed in the substrate via areas 413 by the second contact RIE process 456, to complete formation of the substrate via openings 414. Forming the substrate via openings 414 separately from the contact holes 455 may advantageously improve process latitude and yield. The substrate via etch mask 412 is subsequently removed. Formation of the microelectronic device 400 continues with FIG. 4C.

Referring to FIG. 4C, contacts 411 are formed in the contact holes 455 of FIG. 4A and FIG. 4B, and substrate contact pads 422 are formed in the substrate via openings 414, to make electrical connections to the source/drain pads 408 and to the semiconductor substrate 401, respectively. The contacts 411 and substrate contact pads 422 may be formed concurrently by forming an adhesion liner of titanium, by a sputter process, extending into the contact holes 455 and on the exposed portions of the source/drain pads 408 and the semiconductor substrate 401. Formation of the contacts 411 may continue with forming a barrier liner of titanium nitride on the adhesion liner, extending into the contact holes, and forming a fill plug of tungsten on the barrier liner. The tungsten, barrier liner and adhesion liner on a top surface of the third PMD layer 410 are removed by a CMP process, an etchback process, or a combination of both, leaving the tungsten, barrier liner and adhesion liner in the contact holes to provide the contacts 411. Instances of the contacts 411 in the substrate via openings 414 provide substrate contact pads 422, which make electrical connections to the semiconductor substrate 401. A combination of the substrate via openings 414 and the substrate contact pads 422 provides substrate vias 425 of the microelectronic device 400. In this example, the substrate contact pads 422 extend above the III-N semiconductor layer 403 adjacent to the substrate via openings 414.

Formation of the microelectronic device 400 may continue as disclosed in reference to the microelectronic device 300 of FIG. 3M and FIG. 3N. A pad interconnect layer 420, including source pads 420a and drain pads 420b, is formed over the third PMD layer 410 and the contacts 411. A first ILD layer 426 is formed over the third PMD layer 410 and the members of the pad interconnect layer 420. First vias 429 are formed through the first ILD layer 426 to make electrical connections to the members of the pad interconnect layer 420.

A first interconnect level 432, including first source interconnects 432a and first drain interconnects 432b, is formed over the first ILD layer 426. A second ILD layer 436 may be formed over the first ILD layer 426 and the first interconnect level 432. Second vias 437 may be formed through the second ILD layer 436 to make electrical connections to the members of the first interconnect level 432. A second interconnect level 438 may be formed over the second ILD layer 436. Input/output terminals, not specifically shown, are formed on the members of the second interconnect level 438. A PO layer 440 may be formed over the second ILD layer 436 and the second interconnect level 438. The microelectronic device 400 is subsequently singulated by cutting through the semiconductor substrate 401.

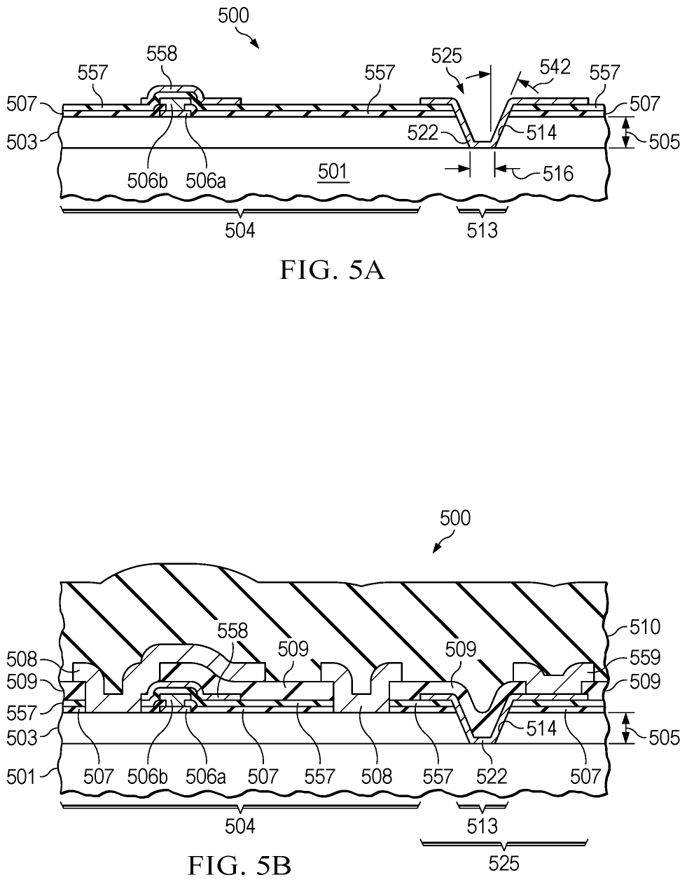

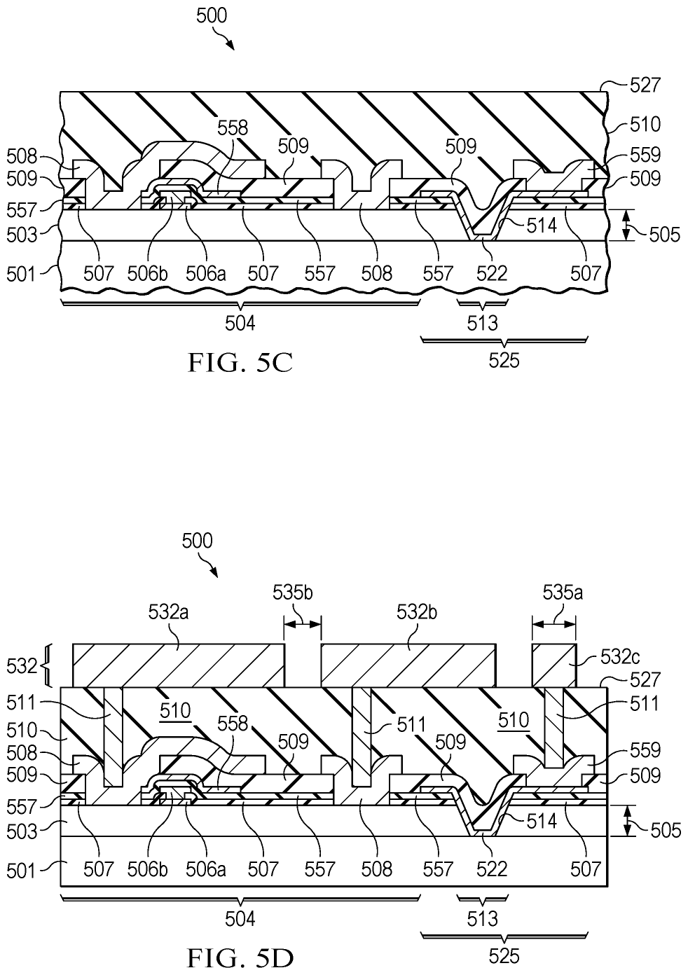

FIG. 5A through FIG. 5D are cross sections of a microelectronic device having a substrate contact through a III-N semiconductor layer to a semiconductor substrate, depicted in successive stages of an example method of formation. Referring to FIG. 5A, the microelectronic device 500 is formed on the semiconductor substrate 501. The semiconductor substrate 501 may be manifested as any of the examples disclosed for the semiconductor substrate 101 of FIG. 1A through FIG. 1AB. The microelectronic device 500 includes a III-N semiconductor layer 503 including III-N semiconductor material over the semiconductor substrate 501, extending across the microelectronic device 500. A thickness 505 of the III-N semiconductor layer 503 may be 1 micron to 5 microns, by way of example. In this example, the microelectronic device 500 includes an active component 504, depicted as a GaN FET 504 formed in and on the III-N semiconductor layer 503. Other active components are within the scope of this example.

A gate work function structure 506a of the GaN FET 504 is formed over the III-N semiconductor layer 503. The gate work function structure 506a provides a desired work function for switching the GaN FET 504 between an ON state and an OFF state. The gate work function structure 506a may include p-type gallium nitride, by way of example. A first PMD layer 507 is formed over the III-N semiconductor layer 503 and the gate work function structure 506a. The first PMD layer 507 may include silicon nitride, and may be formed by an LPCVD process. A gate contact structure 506b is formed through an opening in the first PMD layer 507 to make an electrical connection to the gate work function structure 506a. The gate contact structure 506b may include titanium or titanium tungsten, by way of example.

A field plate dielectric layer 557 is formed over the first PMD layer 507 and the gate contact structure 506b. The field plate dielectric layer 557 may include silicon nitride, and may be formed by an LPCVD process, by way of example. The field plate dielectric layer 557 may be 50 nanometers to 200 nanometers thick, by way of example.

Following forming the field plate dielectric layer 557, one or more substrate via openings 514 are formed through the field plate dielectric layer 557, the first PMD layer 507, and the III-N semiconductor layer 503, exposing the semiconductor substrate 501 in one or more substrate via areas 513. In this example, the substrate via openings 514 may be formed to have sloped sides having a sidewall angle 542 greater than 15 degrees from vertical. The substrate via openings 514 may be formed as disclosed in reference to the substrate via opening 214 of FIG. 2A through FIG. 2I. In some versions of this example, the III-N semiconductor layer 503 may also be removed in the singulation lanes, not specifically shown, concurrently with formation of the substrate via openings 514, as described herein with reference to FIG. 2A through FIG. 2I.

A field plate 558 and substrate contact pads 522 are formed concurrently over the field plate dielectric layer 557. In the versions of this example in which the III-N semiconductor layer 503 is removed in the singulation lanes, a singulation seal, not specifically shown, may also be formed concurrently with the field plate 558 and substrate contact pads 522, the singulation seal extending into the singulation lanes as described herein with reference to FIG. 2A through FIG. 2L. The field plate 558 extends from a source area of the GaN FET 504 over the gate contact structure 506b toward a drain area of the GaN FET 504. The substrate contact pads 522 extend from over the field plate dielectric layer 557 into the substrate via openings 514. The field plate 558 and the substrate contact pads 522, and the singulation seal, if formed, have the same layer structure and composition, as a result of being formed concurrently. The field plate 558 and the substrate contact pads 522 may include titanium or titanium tungsten, and may be 50 nanometers to 150 nanometers thick, by way of example, which may advantageously facilitate planarization of subsequent dielectric layers. The sidewall angle 542 of the substrate via opening 514 being greater than 15 degrees may advantageously enable the substrate contact pads 522 to provide a low resistance from a top surface of the field plate dielectric layer 557 to the semiconductor substrate 501 in the substrate via areas 513 while forming the field plate 558 and substrate contact pads 522 with physical deposition processes such as sputter processes, having semi-conformal deposition characteristics. A combination of the substrate via openings 514 and the substrate contact pads 522 extending into the substrate via openings 514 and making electrical connections to the semiconductor substrate 501 provides substrate vias 525 of the microelectronic device 500. In some versions of this example, the substrate contact pads 522 extend above the III-N semiconductor layer 503 adjacent to the substrate via openings 514. The substrate via opening 514 may have a width 516 at the semiconductor substrate 501 that is less than two times the thickness 505 of the III-N semiconductor layer 503, accruing the advantage of reduced area for the microelectronic device 500. In other versions, the substrate via opening 514 may have the width 516 at the semiconductor substrate 501 that is greater than two times the thickness 505 of the III-N semiconductor layer 503.

Referring to FIG. 5B, a second PMD layer 509 is formed over the field plate dielectric layer 557, the field plate 558, and the substrate contact pads 522. The second PMD layer 509 may include silicon nitride, formed by an LPCVD process. The second PMD layer 509 may be 100 nanometers to 300 nanometers thick, to provide sufficient electric field relief over the III-N semiconductor layer 503 past the field plate 558, while facilitating formation of electrical connects to source and drain areas of the GaN FET 504.

Source/drain pads 508 are formed through the second PMD layer 509, the field plate dielectric layer 557, and the first PMD layer 507, to make electrical connections to source and drain regions of the GaN FET 504, and upper substrate pads 559 are formed through the second PMD layer 509, the field plate dielectric layer 557, and the first PMD layer 507, to make electrical connections to the substrate contact pads 522. The source/drain pads 508 and the upper substrate pads 559 may have a layer structure and composition similar to the source/drain pads 108 of FIG. 1A through FIG. 1D.

A third PMD layer 510 is formed over the second PMD layer 509, the source/drain pads 508, and the upper substrate pads 559. The third PMD layer 510 may include primarily silicon dioxide, and may be formed by a PECVD process. The third PMD layer 510 may be sufficiently thick to fill the substrate via openings 514 and extend above the source/drain pads 508 and the upper substrate pads 559 at all points over the microelectronic device 500. By way of example, the third PMD layer 510 may be 1 micron to 5 microns thick.

Referring to FIG. 5C, the third PMD layer 510 is planarized to provide a planar top surface 527. The third PMD layer 510 may be planarized using a CMP process, an etchback process, or another planarization process. The planar top surface 527 may facilitate formation of interconnect levels over the substrate via openings 514 having linewidths and spaces less than the thickness 505 of the III-N semiconductor layer 503.

Referring to FIG. 5D, contacts 511 are formed through the third PMD layer 510 to make electrical connections to the source/drain pads 508 and the upper substrate pads 559. The contacts 511 may be formed by filling contact holes with a sequence of metals, and removing the metals using a metal CMP process, facilitated by the planar top surface 527 of the third PMD layer 510.

An interconnect layer 532, including source interconnects 532a, drain interconnects 532b, and substrate interconnects 532c, is formed over the third PMD layer 510, making electrical connections to the contacts 511. The interconnect layer 532 may have linewidths 535a and spaces 535b proximate to one or more of the substrate via openings 514 that are less than the thickness 505 of the III-N semiconductor layer 503, facilitated by the planar top surface 527 of the third PMD layer 510, accruing the advantage of a reduced area of the microelectronic device 500. Formation of the microelectronic device 500 may be continued with formation of additional dielectric layers, vias, interconnect levels, and input/output terminals, not specifically shown.

Various features of the examples disclosed herein may be combined in other manifestations of example microelectronic devices. For example, the substrate via openings 114 of FIG. 1Y through FIG. 1AB may have sloped sides similar to the substrate via opening 214 of FIG. 2P through FIG. 2R. The microelectronic device 100 of FIG. 1Y, the microelectronic device 300 of FIG. 3M, the microelectronic device 400 of FIG. 4C, and the microelectronic device 500 of FIG. 5D may also have a substrate via that surrounds the corresponding active component, proximate to a perimeter of the corresponding microelectronic device, similar to the substrate via 225 of FIG. 2P. Any of the microelectronic device 100 of FIG. 1Y through FIG. 1AB, the microelectronic device 200 of FIG. 2P through FIG. 2R, the microelectronic device 300 of FIG. 3M and FIG. 3N, the microelectronic device 400 of FIG. 4C, and the microelectronic device 500 of FIG. 5D may have substrate contact pads that include primarily tungsten or primarily aluminum.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a semiconductor substrate;
a III-N semiconductor layer over the semiconductor substrate, with a substrate via opening extending through the III-N semiconductor layer to the semiconductor substrate;
a substrate contact pad in the substrate via opening, contacting the semiconductor substrate and making an electrical connection to the semiconductor substrate;
a dielectric layer over the substrate contact pad in the substrate via opening, the dielectric layer having a planar surface over the substrate via opening; and
an interconnect metal level over the dielectric layer.

2. The microelectronic device of claim 1, wherein the interconnect metal level extends to an input/output terminal of the microelectronic device.

3. The microelectronic device of claim 1, wherein the interconnect metal level is thicker than the substrate contact pad.

4. The microelectronic device of claim 1, wherein the substrate via opening has a width at the semiconductor substrate that is less than two times a thickness of the III-N semiconductor layer.

5. The microelectronic device of claim 4, wherein the substrate via opening has a length at the semiconductor substrate, perpendicular to the width, that is less than two times the thickness of the III-N semiconductor layer.

6. The microelectronic device of claim 1, further including a singulation lane seal extending over an edge of the III-N semiconductor layer and onto the semiconductor substrate in singulation lanes around a perimeter of the microelectronic device.

7. The microelectronic device of claim 1, wherein the substrate via opening is under a scribe seal structure proximate to a perimeter of the III-N semiconductor layer.

8. The microelectronic device of claim 1, wherein singulation lanes at a perimeter of the microelectronic device are free of the III-N semiconductor layer.

9. The microelectronic device of claim 1, wherein the substrate contact pad extends above the III-N semiconductor layer adjacent to the substrate via opening.

10. The microelectronic device of claim 1, wherein the substrate contact pad fills the substrate via opening, and a top surface of the substrate contact pad is planar above the substrate via opening.

11. The microelectronic device of claim 1, wherein the substrate via opening has sloped sides having a sidewall angle greater than 15 degrees from vertical.

12. A method of forming a microelectronic device, comprising:
forming a substrate via opening through a III-N semiconductor layer to expose a semiconductor substrate;
forming a substrate contact pad over the III-N semiconductor layer, the substrate contact pad extending into the substrate via opening and making an electrical connection to the semiconductor substrate;
forming a dielectric layer over the III-N semiconductor layer and the substrate contact pad, the dielectric layer having a planar surface over the substrate via opening; and
forming an interconnect metal level over the dielectric layer.

13. The method of claim 12, wherein forming the dielectric layer includes planarizing the dielectric layer.

14. The method of claim 12, further including removing the III-N semiconductor layer from singulation lanes at a perimeter of the microelectronic device, concurrently with forming the substrate via opening.

15. The method of claim 12, further including forming an etch mask using a photolithographic process and patterning the substrate contact pad above the III-N semiconductor layer using the etch mask.

16. The method of claim 12, wherein forming the substrate contact pad includes removing the substrate contact pad from over a top surface of the III-N semiconductor layer leaving the substrate contact pad in the substrate via opening.

17. The method of claim 12, wherein the interconnect metal level is thicker than the substrate contact pad.

18. The method of claim 12, wherein:
the substrate via opening surrounds an active component of the microelectronic device and extends adjacent to a perimeter of the III-N semiconductor layer.

19. The method of claim 12, wherein forming the substrate via opening includes:
forming an etch mask over the III-N semiconductor layer using a photolithographic process with a photomask having subresolution geometries, the etch mask having sloped sides around an area for the substrate via opening; and
removing the III-N semiconductor layer where exposed by the etch mask using a dry etch process that erodes the etch mask to form the substrate via opening with sloped sides having sidewall angles greater than 15 degrees from vertical.

20. A microelectronic device, comprising:
a semiconductor substrate;
a III N semiconductor layer over the semiconductor substrate, with a substrate via opening extending through the III N semiconductor layer to the semiconductor substrate; and
a substrate contact pad including primarily tungsten in the substrate via opening, contacting the semiconductor substrate and making an electrical connection to the semiconductor substrate.
